(19) United States
(12) Patent Application Publication
(10) Pub. No.: US 2022/0289976 A1
(43) Pub. Date: Sep. 15, 2022

(54) THERMOSETTING RESIN COMPOSITION, THERMOSETTING RESIN SHEET, ELECTRONIC COMPONENT, AND ELECTRONIC DEVICE

(71) Applicant: TORAY INDUSTRIES, INC., Tokyo (JP)

(72) Inventors: Hisashi OGASAWARA, Otsu-shi (JP); Akira SHIMADA, Otsu-shi (JP); Kazuyuki MATSUMURA, Otsu-shi (JP); Yohei SAKABE, Otsu-shi (JP); Hitoshi ARAKI, Otsu-shi (JP); Masaya JUKEI, Otsu-shi (JP)

(73) Assignee: TORAY INDUSTRIES, INC., Tokyo (JP)

(21) Appl. No.: 17/639,626

(22) PCT Filed: Sep. 25, 2020
(86) PCT No.: PCT/JP2020/036233

§ 371 Date: Mar. 2, 2022

(30) Foreign Application Priority Data
Oct. 1, 2019 (JP) 2019-181164
May 15, 2020 (JP) 2020-086007

(51) Int. Cl. C08L 79/08; C08L 63/00; C08L 71/12; C08L 83/06; C08L 83/16

(52) U.S. Cl. CPC C08L 79/08; C08L 63/00; C08L 71/12; C08L 83/06; C08L 83/16; C08L 2201/08; C08L 2203/20

(57) ABSTRACT

Provided are: a thermosetting resin composition, for use in an organic material suited to high frequency use, that has outstanding low dielectric tangent, heat resistance, flexibility, and ease of workability; a thermosetting resin sheet; an electronic component; and an electronic device. The present invention is a thermosetting resin composition that includes the following constituents (A1)-(C). (A1) Polyimide resin: a polyimide resin including a diamine residue with formula (8) and/or formula (9) (in formula (8), a, b, c, and d are integers 1 or greater that meet the conditions a+b=6-17 and c+d=8-19, and the dashed lines denote carbon-carbon single bonds or carbon-carbon double bonds) (in formula (9), e, f, g, and h are integers 1 or greater that meet the conditions e+f=5-16 and g+h=8-19, and the dashed lines denote carbon-carbon single bonds or carbon-carbon double bonds). (B) Phenylene ether resin: a phenylene ether resin that has a number average molecular weight of 500-5,000 and, at a terminal of a molecular chain, includes at least one cross-linked functional group selected from the group consisting of a phenolic hydroxyl group, an acryl group, a vinyl group, and an epoxy group. (C) Maleimide resin: a maleimide resin.

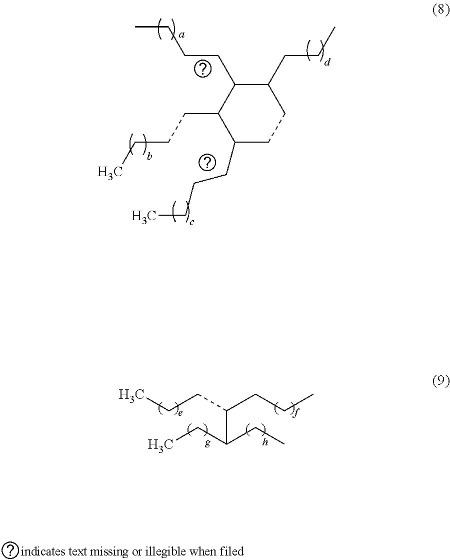

### TECHNICAL FIELD

The present invention relates to a thermosetting resin composition, a thermosetting resin sheet, an electronic component, and an electronic device.

### BACKGROUND ART

Currently, the traffic volume of data communication around the world is increasing year by year, and data processing methods in use are becoming more and more complicated to serve for increased practical application of Al and big data. To cope with this, it is essential to improve techniques to perform faster data communication and faster data processing, and candidate solutions now under study include the use of higher communication frequencies and the development of electronic instruments with capacities for higher signal frequencies. There are many approaches to the development of electronic instruments with capacities for higher frequencies in actual data processing, including the use of materials with improved electrical characteristics, better circuit designs, and efficient signal processing methods. In particular, an effective method is to use insulating layers and protective layers of organic materials with decreased dissipation factors.

On the other hand, conventional organic materials such as thermosetting resins with high durability and processability in particular contain many polar functional groups that act to develop intermolecular cohesive forces and high adhesiveness, and therefore, they are relatively high in dissipation factor and difficult to apply to higher frequencies.

To solve this problem, there have been some proposals including (1) the method of using a thermoplastic resin with fewer polar functional groups as primary component and blending a thermosetting resin with it (Patent document 1), (2) the method of using a thermosetting resin that leaves no polar functional residues after reaction (Patent document 2), and (3) the method of blending inorganic particles with a low dissipation factor (Patent document 3).

### PRIOR ART DOCUMENTS

### Patent Documents

Patent document 1: Japanese Unexamined Patent Publication (Kokai) No. 2004-161828

Patent document 2: Japanese Unexamined Patent Publication (Kokai) No. 2003-252957

Patent document 3: Japanese Unexamined Patent Publication (Kokai) No. 2002-100238

### SUMMARY OF INVENTION

### Problems to be Solved by the Invention

However, the method of (1) has disadvantages relating to heat resistance and adhesion strength as shown in, for example, dynamic viscoelasticity measurement. In the case of the methods of (2) and (3), on the other hand, the film strength is so low before and after curing that there are disadvantages relating to flexibility and limited applications and conditions for use at high elongation percentages. In the case of the method of (3), furthermore, the existence of inorganic particles imposes limitations on the fine processability of viaholes, etc. The above description shows that it is impossible for the conventional techniques to meet all requirements for low dissipation factor, high heat resistance, high flexibility, and high processability.

In view of this, the main object of the present invention is to solve the above problems to provide a thermosetting resin composition that is low in dissipation factor and high in heat resistance, flexibility, and processability to serve for producing an organic material suitable for high frequency applications, and also provide a thermosetting resin sheet, an electronic component, and an electronic device produced therefrom.

### Means of Solving the Problems

To solve the above problems, the present inventors made intensive studies aiming to develop a thermosetting resin composition having good characteristics at high frequencies, and as a result, they arrived at the present invention after finding that a highly reliable thermosetting resin composition that is low in dissipation factor and high in heat resistance, flexibility, and processability can be formed from a combination of a polyimide resin, a thermosetting resin, and a phenylene ether resin that have specific structures.

Specifically, the first embodiment of the present invention is as described below.

A thermosetting resin composition including the components of (A1), (B), and (C) specified below.

Polyimide resin (A1): a polyimide resin containing a diamine residue as represented by the formula (8) and/or the formula (9).

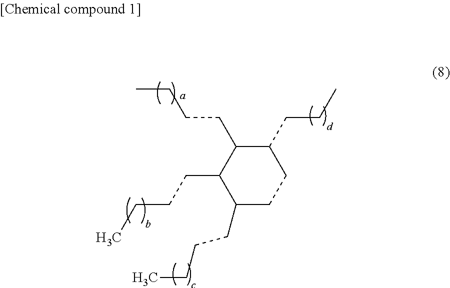

(In the formula (8), a, b, c, and d are each an integer number of 1 or higher and satisfy the relations of a+b=6 to 17, and c+d=8 to 19, and each broken line represents either a carbon-carbon single bond or a carbon-carbon double bond.)

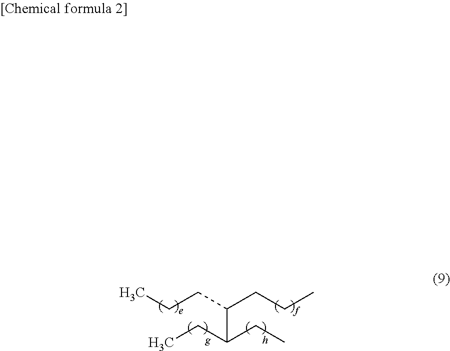

(In the formula (9), e, f, g, and h are each an integer number of 1 or higher and satisfy the relations of e+f=5 to 16, and g+h=8 to 19, and each broken line represents either a carbon-carbon single bond or a carbon-carbon double bond.)

Phenylene ether resin (B): a phenylene ether resin having a number average molecular weight of 500 or more and 5,000 or less and having at least one crosslinkable functional group selected from the group consisting of phenolic hydroxyl group, acryl group, vinyl group, and epoxy group located at a molecular chain end.

Maleimide resin (C): a maleimide resin.

Alternatively, the second embodiment of the present invention is as described below.

A thermosetting resin composition including the components of (A2), (B), and (C) specified below.

Polyimide resin (A2): a polyimide resin containing a diamine residue as represented by the formula (1).

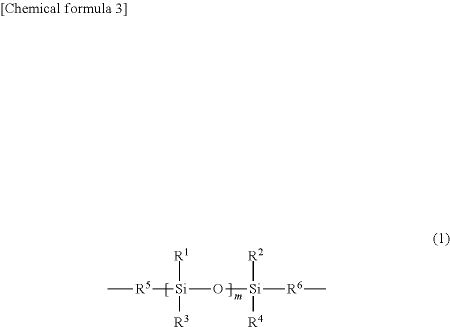

(In the formula (1), m represents an integer number of 1 to 60; R⁵ and R⁶ may be identical to or different from each other and they each represent an alkylene group containing 1 to 30 carbon atoms or a phenylene group; and R¹ to R⁴ may be identical to or different from each other and they each represent an alkyl group containing 1 to 30 carbon atoms, a phenyl group, or a phenoxy group.)

Phenylene ether resin (B): a phenylene ether resin having a number average molecular weight of 500 or more and 5,000 or less and having at least one crosslinkable functional group selected from the group consisting of phenolic hydroxyl group, acryl group, vinyl group, and epoxy group located at a molecular chain end.

Maleimide resin (C): a maleimide resin.

### Advantageous Effects of the Invention

The present invention provides a thermosetting resin composition that is low in dissipation factor and high in heat resistance, flexibility, and processability to serve for producing an organic material suitable for high frequency applications, and also provides a thermosetting resin sheet, an electronic component, and an electronic device produced therefrom.

### BRIEF DESCRIPTION OF THE DRAWINGS

FIG. 1 is a schematic diagram of a coplanar waveguide-fed microstrip antenna, which is a kind of planar antenna.

FIG. 2 is a schematic diagram showing a cross section of a semiconductor package that contains an IC chip (semiconductor element), a redistribution layer, a molding resin layer, and an antenna element.

### DESCRIPTION OF PREFERRED EMBODIMENTS

The thermosetting resin composition according to the present invention contains the components of (A1), (B), and (C) specified below.

Polyimide resin (A1): a polyimide resin containing a diamine residue as represented by the formula (8) and/or the formula (9)

Phenylene ether resin (B): a phenylene ether resin having a number average molecular weight of 500 or more and 5,000 or less and having at least one crosslinkable functional group selected from the group consisting of phenolic hydroxyl group, acryl group, vinyl group, and epoxy group located at a molecular chain end

Maleimide resin (C): a maleimide resin.

The polyimide resin (A1) used for the present invention is not particularly limited as long as it is a polyimide resin containing a diamine residue as represented by the formula (8) and/or the formula (9), but it is preferably one that is produced mainly through a reaction between a tetracarboxylic dianhydride and a diamine and contains a residue of the tetracarboxylic dianhydride and a residue of the diamine. Here, the polyimide resin (A1) used for the present invention contains a diamine residue as represented by the formula (8) and/or the formula (9).

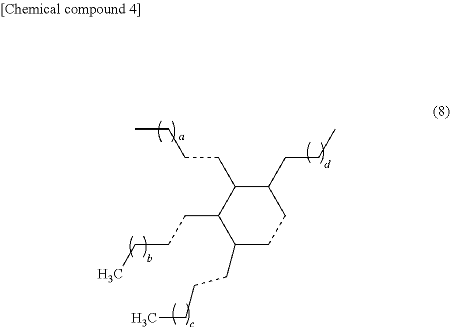

(In the formula (8), a, b, c, and d are each an integer number of 1 or higher and satisfy the relations of a+b=6 to 17, and c+d=8 to 19, and each broken line represents either a carbon-carbon single bond or a carbon-carbon double bond.)

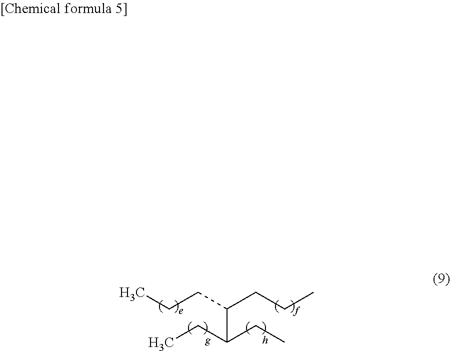

(In the formula (9), e, f, g, and h are each an integer number of 1 or higher and satisfy the relations of e+f=5 to 16, and g+h=8 to 19, and each broken line represents either a carbon-carbon single bond or a carbon-carbon double bond.)

A structure as represented by the formula (8) or the formula (9) has the backbone of a dimer acid that is in the form of a dimer of an unsaturated fatty acid such as linoleic acid and oleic acid, and from the viewpoint of giving a cured film with high reliability, it is preferable for the structure not to contain a double bond. The use of a structure as represented by the formula (10) is particularly preferable from the viewpoint of ensuring good economy and obtaining a cured film with a desired elongation percentage.

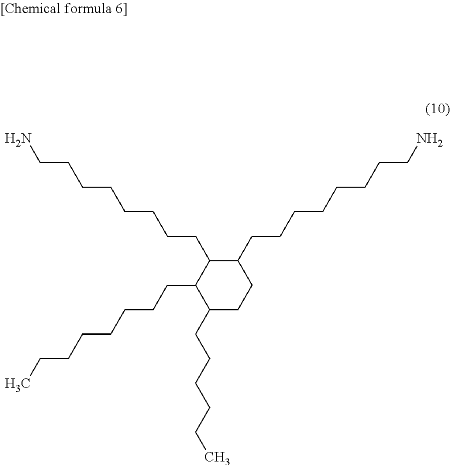 [SMILES: CCCCCCCCC1C(CCCCCC)CCC(CCCCCCCCN)C1CCCCCCCCN]

Specific examples of a diamine having a structure as represented by the formula (8) include commercial products of dimer diamines such as Versamine (registered trademark) 551, Versamine (registered trademark) 552, both manufactured by BASF, Priamine (registered trademark) 1073, Priamine (registered trademark) 1074, and Priamine (registered trademark) 1075, all manufactured by Croda Japan K.K. Of these, Versamine (registered trademark) 551 and Priamine (registered trademark) 1074 are dimer diamine compounds as represented by the formula (11), whereas Versamine (registered trademark) 552, Priamine (registered trademark) 1073, and Priamine (registered trademark) 1075 are dimer diamine compounds as represented by the formula (10).

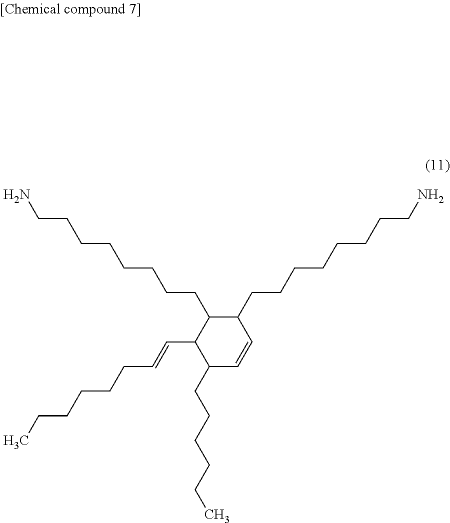 [SMILES: CCCCCC/C=C/C1C(CCCCCC)C=CC(CCCCCCCCN)C1CCCCCCCCN]

Alternatively, a mixture of a trimer triamine and a dimer diamine may be adopted. Commercial products of trimer triamine and dimer diamine include Priamine (registered trademark) 1071 manufactured by Croda Japan K.K.

When the polyimide resin (A1) contains a diamine residue of a structure as represented by the formula (8) and/or the formula (9), it is preferable for the dimer acid structure to account for 1 mol % or more and 30 mol % or less, and more preferably 1 mol % or more and 15 mol % or less. If the content is 1 mol % or more, it is possible to ensure a low relative dielectric constant and a low dissipation factor. If it is less than 30 mol %, on the other hand, an increased heat resistance can be ensured.

Alternatively, the thermosetting resin composition according to the present invention contains the components of (A2), (B), and (C) specified below.

Polyimide resin (A2): a polyimide resin containing a diamine residue as represented by the formula (1)

Phenylene ether resin (B): a phenylene ether resin having a number average molecular weight of 500 or more and 5,000 or less and having at least one crosslinkable functional group selected from the group consisting of phenolic hydroxyl group, acryl group, vinyl group, and epoxy group located at a molecular chain end

Maleimide resin (C): a maleimide resin.

The polyimide resin (A2) used for the present invention is not particularly limited as long as it is a polyimide resin containing a diamine residue as represented by the formula (1), but it is preferably one that is produced mainly through a reaction between a tetracarboxylic dianhydride and a diamine and contains a residue of the tetracarboxylic dianhydride and a residue of the diamine. Here, the polyimide resin (A2) used for the present invention contains a diamine residue as represented by the formula (1) given above.

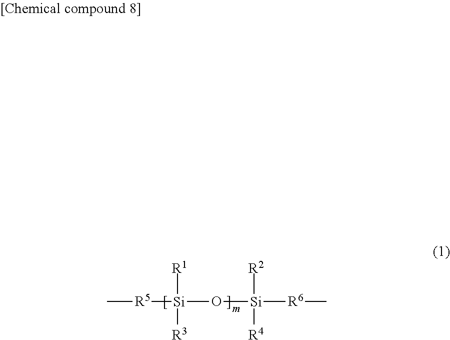

(In the formula (1), m represents an integer number of 1 to 60; R⁵ and R⁶ may be identical to or different from each other and they each represent an alkylene group containing 1 to 30 carbon atoms or a phenylene group; and R¹ to R⁴ may be identical to or different from each other and they each represent an alkyl group containing 1 to 30 carbon atoms, a phenyl group, or a phenoxy group.)

The alkyl groups containing 1 to 30 carbon atoms to be used suitably as R¹ to R⁴ are not particularly limited, but preferable ones include the methyl group, ethyl group, propyl group, and butyl group. The alkylene groups containing 1 to 30 carbon atoms to be used suitably as R⁵ and R⁶ are not particularly limited either, but preferable ones include the methylene group, ethylene group, propylene group, butylene group. Here, these alkyl groups and alkylene groups may not necessarily have linear structures.

The number of bonds in the siloxane structure, i.e., m in the formula (1), is preferably 1 or more and 60 or less, and more preferably 1 or more and 40 or less. If it is 60 or less, it ensures an improved heat resistance.

Specific examples of a diamine having a structure as represented by the formula (1) include, but not limited to, 1,1,3,3-tetramethyl-1,3-bis(4-aminophenyl)disiloxane, 1,1,3,3-tetraphenoxy-1,3-bis(4-aminoethyl)disiloxane, 1,1,3,3,5,5-hexamethyl-1,5-bis(4-aminophenyl)trisiloxane, 1,1,3,3-tetraphenyl-1,3-bis(2-aminoethyl)disiloxane, 1,1,3,3-tetraphenyl-1,3-bis(3-aminopropyl)disiloxane, 1,1,5,5-tetraphenyl-3,3-dimethyl-1,5-bis(3-aminopropyl)trisiloxane, 1,1,5,5-tetraphenyl-3,3-dimethoxy-1,5-bis(4-aminobutyl)trisiloxane, 1,1,5,5-tetraphenyl-3,3-dimethoxy-1,5-bis(5-aminopentyl)trisiloxane, 1,1,3,3-tetramethyl-1,3-bis(2-aminoethyl)disiloxane, 1,1,3,3-tetramethyl-1,3-bis(3-aminopropyl)disiloxane, 1,1,3,3-tetramethyl-1,3-bis(4-aminobutyl)disiloxane, 1,3-dimethyl-1,3-dimethoxy-1,3-bis(4-aminobutyl)disiloxane, 1,1,5,5-tetramethyl-3,3-dimethoxy-1,5-bis(2-aminoethyl)trisiloxane, 1,1,5,5-tetramethyl-3,3-dimethoxy-1,5-bis(4-aminobutyl)trisiloxane, 1,1,5,5-tetramethyl-3,3-dimethoxy-1,5-bis(5-aminopentyl)trisiloxane, 1,1,3,3,5,5-hexamethyl-1,5-bis(3-aminopropyl)trisiloxane, 1,1,3,3,5,5-hexaethyl-1,5-bis(3-aminopropyl)trisiloxane, and 1,1,3,3,5,5-hexapropyl-1,5-bis(3-aminopropyl)trisiloxane. In addition, commercial products corresponding to these diamines include LP7100, PAM-E, KF8010, X-22-161A, X-22-161B, KF8012, and KF8008, all manufactured by Shin-Etsu Chemical Co., Ltd.

When the polyimide resin (A2) contains a diamine residue as represented by the formula (1), it is preferable for the siloxane structure in the formula (1) to account for 20 mol % or more and 80 mol % or less, and more preferably 30 mol % or more and 70 mol % or less. If the content is 20 mol % or more, the number of structures with low polarity increases, ensuring a low relative dielectric constant and a low dissipation factor. If it is 80 mol % or less, on the other hand, it can serve to ensure an improved modulus at high temperatures and an increased heat resistance.

It is preferable for the polyimide resin to be the polyimide resin (A1) and the polyimide resin (A2). The relative dielectric constant and dissipation factor can be further decreased if diamine residues as represented by the formula (1) and the formula (8) and/or the formula (9) are contained.

It is preferable that in the polyimide resin (A2), diamine residues represented by the formula (1) account for 20 to 80 mol % of all diamine residues, which account for 100 mol %, in the polyimide while at the same time, in the (A1) polyimide, diamine residues represented by the formula (8) or formula (9) altogether account for 1 to 30 mol % of all diamine residues, which account for 100 mol %, in the polyimide.

It is preferable for the polyimide resin (A1) and the polyimide resin (A2) to have an imide group equivalent of 350 or more and 1,000 or less. It is more preferably 380 or more and 900 or less. It is preferable for the imide group equivalent to be in the aforementioned range of 350 or more and 1,000 or less after imidization reaction. The imide group equivalent is defined as the molecular weight per mole of imide groups in the polyimide resin. The imide group equivalent is calculated for one unit based on the molecular weights of the tetracarboxylic dianhydride and the diamine. For example, in the case of the polyimide resin represented by the formula (2) given below, there exist 2 moles of imide groups in a unit. Since the polyimide resin has a molecular weight of 684.71, the imide group equivalent is 342.36. For the polyimide resin (A1) and the polyimide resin (A2), an imide group equivalent of 350 or more leads to a smaller imide group concentration and a lower polarity, ensuring a lower dissipation factor. If the imide group equivalent is 1,000 or less, on the other hand, the heat resistance will improve due to molecular aggregation caused by imide groups.

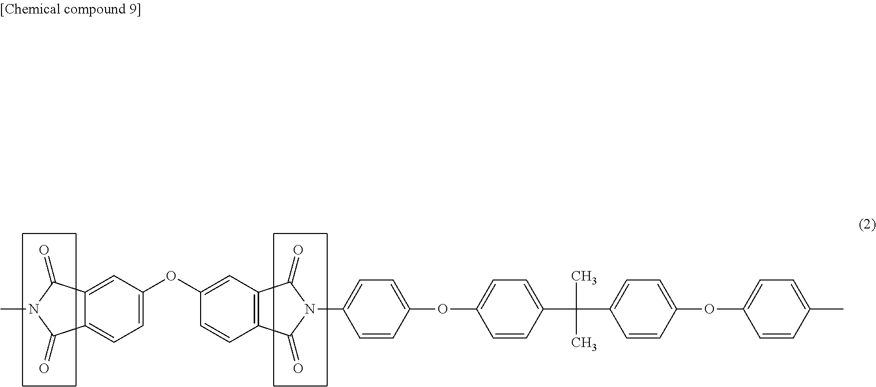

It is preferable for the polyimide resin (A1) and the polyimide resin (A2) to contain a diamine residue that has a structure as represented by the formula (3). In the formula (3), R⁷ and R⁸ may be identical to or different from each other and they each represent an alkyl group containing 1 to 30 carbon atoms, an alkoxy group, a fluoroalkyl group, a phenyl group, or a phenoxy group.

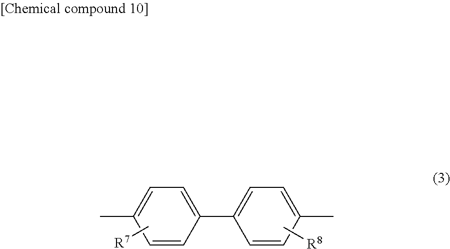

If the polyimide resin (A1) and the polyimide resin (A2) contain a diamine residue that has a structure as represented by the formula (3), the structure of the resin will be high in linearity and rigidity, leading to an increased mechanical strength. From the viewpoint of increasing the mechanical strength, the diamine residue that has a structure as represented by the formula (3) preferably accounts for 30 mol % or more, more preferably 40 mol % or more, of the total diamine residue content. From the viewpoint of achieving strong adhesiveness to ensure increased adhesion strength to metals such as copper, furthermore, the content is preferably 70 mol % or less, and more preferably 60 mol % or less. R⁷ and R⁸ are not particularly limited as long as they are each an alkyl group containing 1 to 30 carbon atoms, an alkoxy group, a fluoroalkyl group, a phenyl group, or a phenoxy group, but it is particularly preferable for R⁷ and R⁸ to be each a trifluoromethyl group. Since fluorine has a large atomic radius, it acts to increase the free volume in the trifluoromethyl group, leading to a lower relative dielectric constant and a lower dissipation factor. Specific examples of diamines as represented by the formula (3) include, but not limited to, 2,2′-bis(trifluoromethyl) benzidine, 2,2′-dimethylbiphenyl-4,4′-diamine, 2,2′-diethylbiphenyl-4,4′-diamine, 2,2′-dimethoxybiphenyl-4,4′-diamine, and 2,2′-diethoxybiphenyl-4,4′-diamine.

The polyimide resin (A1) and the polyimide resin (A2) each preferably have a glass transition temperature (hereinafter occasionally referred to as Tg) of 100° C. or more and 200° C. or less, and more preferably 110° C. or more and 180° C. or less. If it is 100° C. or more, it ensures an improved heat resistance, thereby serving to prevent peeling during solder reflow operation. If the Tg of the polyimide resin (A1) and the polyimide resin (A2) is 200° C. or less, the thermosetting composition before curing has improved flowability during heating and pressing, leading to stronger adhesion to a base material. To determine the Tg to be used for the present invention, a test piece was prepared by forming a polyimide resin or a thermosetting resin composition with a thickness of about 20 to 100 μm and heat-curing it at a predetermined temperature, and subjected to measurement using a dynamic viscoelasticity measuring apparatus in the tensile mode under the conditions of a frequency of 1 Hz and a heating rate of 5° C./min, followed by calculation from the peak value of tan δ.

It is preferable for the polyimide resin (A1) and the polyimide resin (A2) to contain an acid dianhydride residue as represented by the formula (4) given below. Such an acid dianhydride residue has a large molecular weight to serve for decreasing the imide group concentration in the polyimide resin and also has an alicyclic structure to serve for ensuring a low polarity, leading to a lower relative dielectric constant and a lower dissipation factor. Having an alicyclic structure, furthermore, it acts to suppress the molecular motion and increase the heat resistance. From the viewpoint of reducing the relative dielectric constant and the dissipation factor, the acid dianhydride residue represented by the formula (4) preferably accounts for 50 mol % or more, and more preferably 70 mol % or more, of the total quantity of acid dianhydride residues.

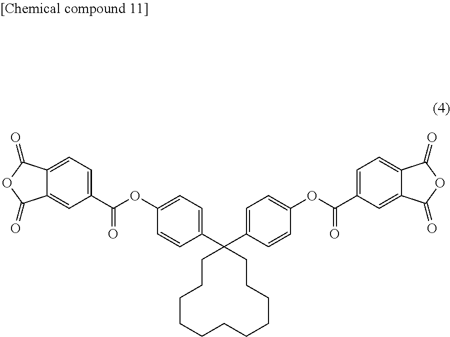 [SMILES: O=C(Oc1ccc(C2(c3ccc(OC(=O)c4ccc5c(c4)C(=O)OC5=O)cc3)CCCCCCCCCCC2)cc1)c1ccc2c(c1)C(=O)OC2=O]

For the present invention, the polyimide resin (A1) and the polyimide resin (A2) each preferably have a weight average molecular weight of 5,000 or more and 1,000,000 or less. In the case where two or more polyimide resins are contained, it is enough if one of them has a weight average molecular weight in the above range. If having a weight average molecular weight of 5,000 or more, the resin will suffer a less decrease in mechanical strength and a less decrease in adhesion strength. It is preferably 10,000 or more. If having a weight average molecular weight of 1,000,000 or less, on the other hand, the resin will not undergo an increase in melt viscosity during heating and will suffer a less decrease in adhesion strength. It is preferably 500,000 or less. Here, for the present invention, the weight average molecular weight is measured by gel permeation chromatography (GPC) and converted in terms of polystyrene.

The polyimide resin used for the present invention may contain other diamine residues in addition to those diamine residues described above unless they impair the good effects of the present invention. For example, such residues of diamine compounds include diamines having one benzene ring such as 1,4-diaminobenzene, 1,3-diaminobenzene, 2,4-diaminotoluene, and 1,4-diamino-2,5-dihalogenobenzene; diamines having two benzene rings such as bis(4-aminophenyl)ether, bis(3-aminophenyl)ether, bis(4-aminophenyl)sulfone, bis(3-aminophenyl)sulfone, bis(4-aminophenyl)methane, bis(3-aminophenyl)methane, bis(4-aminophenyl)sulfide, bis(3-aminophenyl)sulfide, 2,2-bis(4-aminophenyl)propane, 2,2-bis(3-aminophenyl)propane, 2,2-bis(4-aminophenyl)hexafluoropropane, o-dianisidine, o-tolidine, and tolidinesulfonic acid; diamines having three benzene rings such as 1,4-bis(4-aminophenoxy)benzene, 1,4-bis(3-aminophenoxy)benzene, 1,4-bis(4-aminophenyl)benzene, 1,4-bis(3-aminophenyl)benzene, α,α′-bis(4-aminophenyl)-1,4-diisopropylbenzene, α,α′-bis(4-aminophenyl)-1,3-diisopropylbenzene; and diamines having four or more benzene rings such as 2,2-bis[4-(4-aminophenoxy)phenyl]propane, 2,2-bis[4-(4-aminophenoxy)phenyl]hexafluoro propane, 2,2-bis[4-(4-aminophenoxy)phenyl]sulfone, 4,4′-(4-aminophenoxy)biphenyl, 9,9-bis(4-aminophenyl)fluorene, and 5,10-bis(4-aminophenyl)anthracene. It is noted that such other diamine residues are not limited to the above.

The polyimide resin to be used for the present invention may contain other acid dianhydride residues in addition to those acid dianhydride residues described above unless they impair the good effects of the present invention. Such other acid dianhydride residues to be contained are not particularly limited, and good examples are residues of such acid dianhydrides as pyromellitic anhydride (PMDA), oxydiphthalic acid dianhydride (ODPA), 3,3′,4,4′-benzophenonetetracarboxylic acid dianhydride (BTDA), 3,3′,4,4′-biphenyltetracarboxylic acid dianhydride (BPDA), 3,3′,4,4′-diphenylsulfonetetracarboxylic acid dianhydride (DSDA), 2,2′-bis[(dicarboxyphenoxy)phenyl]propane dianhydride (BSAA), 4,4′-hexafluoroisopropylidenediphthalic acid dianhydride (6FDA), and 1,2-ethylene bis(anhydrotrimellitate) (TMEG). It is noted that good acid dianhydride residues are not limited to the above.

There are no particular limitations on the method to be used for producing the polyimide resin (A1) or the polyimide resin (A2), but it is preferable to adopt an ordinary method in which an acid anhydride monomer and a diamine monomer are dissolved in an appropriate solvent, by making good use of the high solubility of dimer acid structures and siloxane structures, and mixed to cause a reaction, followed by synthesis through thermal cyclization or chemical cyclization.

The residue of the tetracarboxylic acid dianhydride and the residue of the diamine used above preferably have a structure having the features of (1) containing fewer benzene rings, (2) having a large molecular weight to ensure a high bulkiness, or (3) being a low-polarity group such as an aliphatic group and siloxane group. Having such a structure serves to decrease the concentration of high-polarity imide groups and increase the free volume among molecular chains, thereby ensuring a low relative dielectric constant and a low dissipation factor.

The polyimide resin used for the present invention may be composed only of polyimide structural units or may be a copolymer containing other structures as copolymerization components in addition to polyimide structural units. Alternatively, a precursor of a polyimide structural unit (polyamic acid structure) may be contained. A mixture thereof may also be useful. Furthermore, any of these may be mixed with another polyimide resin of a dissimilar structure. When another polyimide resin of a dissimilar structure is mixed, it is preferable for the polyimide resin according to the present invention to account for 50 mol % or more. The structure to be used for such copolymerization or mixing may be of any appropriate type and in any appropriate quantity unless it impairs the good effects of the present invention.

There are no particular limitations on the method to be used to synthesize the polyimide resin (A1) and the polyimide resin (A2) used for the present invention, and they can be synthesized from a diamine and a tetracarboxylic acid dianhydride by a generally known method. For example, a polyimide precursor is prepared by (1) a method in which a tetracarboxylic acid dianhydride and a diamine compound (which may be partly substituted by an aniline derivative) are reacted at a low temperature, (2) a method in which a tetracarboxylic acid dianhydride and an alcohol are reacted to form a diester, which is then reacted with a diamine (which may be partly substituted by an aniline derivative) in the presence of a condensation agent, or (3) a method in which a tetracarboxylic acid dianhydride and an alcohol are reacted to form a diester and then the remaining two carboxylic acid groups are converted into acid chlorides, which are then reacted with a diamine (which may be partly substituted by an aniline derivative). Subsequently, synthesis is performed by a generally known imidization method.

When applying them to a thermosetting composition, either a method in which they are added in the form of a polyamic acid so that imidization occurs during heat curing or a method in which a polyamic acid is polymerized and imidized immediately so that they are added in the form of a structure having a closed ring may be adopted.

In the thermosetting composition according to the present invention, it is preferable for the polyimide resin to account for 30 wt % or more and less than 90 wt %, and more preferably 40 wt % or more and 80 wt % or less, relative to 100 wt % of the thermosetting composition. If it is 30 wt % or more, the quantity of polymer components will increase and serve to ensure improved flexibility. If it is 90 wt % or less, the quantity of the thermosetting resin components will increase to reduce the melt viscosity during thermocompression bonding, thereby ensuring an improved adhesion strength between the adhesive composition and a layered body.

The thermosetting resin composition according to the present invention contains a phenylene ether resin (B), which is a phenylene ether resin having a number average molecular weight of 500 or more and 5,000 or less and having at least one crosslinkable functional group selected from the group consisting of phenolic hydroxyl group, acryl group, vinyl group, and epoxy group located at a molecular chain end. The phenylene ether resin referred to for the present invention is not particularly limited as long as the resin has a structure in which a structure as specified by the formula (5) is contained repeatedly. It is preferable, however, that a plurality of structures as specified by the formula (5) be contained in the structure of the resin, and it is particularly preferable that a maximum possible number of structures as specified by the formula (5) be contained as repeating units in the structure of the resin. Here, the phenylene ether resin referred to for the present invention may be a copolymer with a different structure as long as a structure as specified by the formula (5) is contained in the structure of the resin.

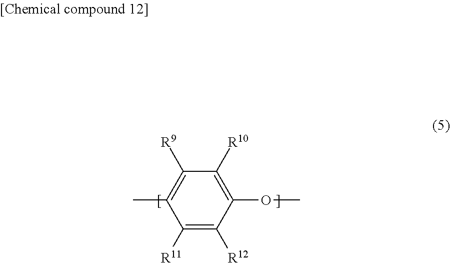

In the formula (5), R⁹ to R¹² may be identical to or different from each other and they each represent a hydrogen atom, a halogen atom, an alkyl group containing 1 to 30 carbon atoms, an alkoxy group, a fluoroalkyl group, a phenyl group, or a phenoxy group.

The phenylene ether resin (B) independently shows a low dissipation factor, and if added to a thermosetting resin composition, it acts to reduce its dissipation factor. The phenylene ether resin (B) has a number average molecular weight of 500 or more and 5,000 or less. It is more preferable for the phenylene ether resin (B) to have a number average molecular weight of 1,000 or more and 4,000 or less. If the number average molecular weight is 500 or more, it serves to reduce the crosslink density and improve the toughness of the thermosetting resin composition. If it is 5,000 or less, it serves to increase the compatibility with other components such as polyimide and allow the thermosetting resin composition to have a uniform structure and stable physical properties. The phenylene ether resin (B) used for present invention has at least one crosslinkable functional group selected from the group consisting of phenolic hydroxyl group, acryl group, vinyl group, and epoxy group located at a molecular chain end. These crosslinkable functional groups preferably exist at both ends of the molecular chain, but may exist only at one molecular chain end. If containing these crosslinkable functional groups, the phenylene ether resin (B) can form a cross-linked structure as it is heat-cured, thereby developing an improved mechanical strength, heat resistance, and adhesiveness. Of these crosslinkable functional groups, the vinyl group is preferable as the crosslinkable functional group to be contained in the phenylene ether resin (B). A thermosetting resin composition thermally crosslinked through the vinyl group is low in polarity and can ensure a low relative dielectric constant and a low dissipation factor. Such resins include OPE-2st, manufactured by Mitsubishi Gas Chemical Co., Inc.

The content of the phenylene ether resin (B) is not particularly limited, but it is preferably 5 wt % or more and 50 wt % or less, more preferably 10 wt % or more and 40 wt % or less, relative to 100 wt % of the thermosetting resin composition. If the content is 5 mol % or more, it serves to reduce the relative dielectric constant and the dissipation factor. If it is 50 or less, it ensures an improved toughness and improved adhesiveness.

The thermosetting resin composition according to the present invention contains a maleimide resin (C). The inclusion of the maleimide resin (C) works to increase the heat resistance and improve the adhesion strength, and if a phenylene ether resin containing a vinyl group as the crosslinkable functional group at a molecular chain end is used as the phenylene ether resin (B), furthermore, the maleimide resin (C) can act together with the phenylene ether resin (B) to decrease the heat-curing reaction temperature down to 180° C. or less. From the viewpoint of providing a low-viscosity solution of the thermosetting resin composition, the maleimide resin (C) is only required to be a maleimide resin that can be dissolved in an organic solvent and otherwise there are no particular limitations thereon. Good examples of the maleimide resin (C) include phenylmethane maleimide, meta-phenylene bismaleimide, 4,4′-diphenylmethane bismaleimide, bis(3-ethyl-5-methyl-4-maleimidephenyl)methane, 2,2′-bis[4-(4-maleimidephenoxy)phenyl]propane, 4-methyl-1,3-phenylene bismaleimide, 1,6-bismaleimide-(2,2,4-trimethyl)hexane, 4,4-diphenyl ether bismaleimide, 4,4-diphenylsulfone bismaleimide, polyphenylmethane maleimide, novolac-type maleimide compounds, biphenylaralkyl type maleimide compounds, and prepolymers of these maleimide resins.

The content of the maleimide resin (C) is not particularly limited, but it is preferably 1 wt % or more and 50 wt % or less, and more preferably 3 wt % or more and 40 wt % or less, relative to 100 wt % of the thermosetting resin. If it is 1 wt % or more, it serves to accelerate the crosslinking reaction of a phenylene ether resin that has a vinyl group at a molecular chain, leading to an increased heat resistance. If it is 50 or less, it serves to prevent the modulus from increasing, thereby ensuring a high toughness. The above examples of the maleimide resin (C) may be used singly or as a combination of two or more thereof.

It is preferable for the maleimide resin (C) to contain polymaleimide resin molecules each having N maleimide groups (each N is an integer number and the average of N's is larger than 2 and smaller than 30). If the number of maleimide groups is larger than 2, it ensures a high crosslink density to ensure a high adhesion strength. If the number of maleimide groups is smaller than 30, it ensures a high compatibility with other resins.

Examples of such a polymaleimide resin include maleimide resins as represented by the formula (6) given below.

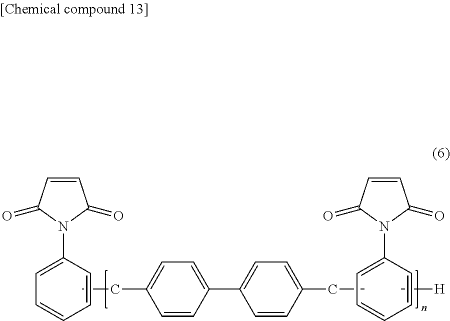

The thermosetting resin composition according to the present invention preferably contains an epoxy resin (D). The epoxy resin (D) to be used for the present invention is not particularly limited, but from the viewpoint of the flexibility in the B stage and the strength of adhesion to a substrate, it is preferably an epoxy resin that is liquid at room temperature.

The epoxy resin that is liquid at room temperature used herein shows a viscosity of 150 Pa·s or less at 1.013×10⁵ N/m² and 25° C. For the epoxy resin (D), preferred liquid epoxy resins include, for example, bisphenol A type epoxy resin, bisphenol F type epoxy resin, alkylene oxide-modified epoxy resin, and glycidyl amine type epoxy resin. Commercial products corresponding to these epoxy resins include JER825, JER827, JER828, JER806, JER807, JER801N, JER802, JER604, JER630, JER630LSD (manufactured by Mitsubishi Chemical Corporation), Epicron 840S, Epicron 850S, Epicron 830S, Epicron 705, Epicron 707(manufactured by DIC Corporation), YD127, YD128, PG207N, PG202 (manufactured by Nippon Steel Chemical Co., Ltd.), TEPIC-PAS B22, TEPIC-VL, TEPIC-FL, FOLDI E101, FOLDI E201 (manufactured by Nissan Chemical Industries, Ltd.), A1, A2, and A3 (manufactured by Croda).

The content of the epoxy resin (D) is not particularly limited, but it is preferably 1 wt % or more and 50 wt % or less, and more preferably 3 wt % or more and 40 wt % or less, relative to 100 wt % of the thermosetting resin composition. If it is 1 or less, the B stage sheet will have a low melt viscosity in the heating step and show a high adhesiveness to the base material. The above examples of the epoxy resin (D) may be used singly or as a combination of two or more thereof.

The thermosetting resin composition according to the present invention preferably contains a curing accelerator (E). The use the epoxy resin (D) and the curing accelerator (E) in combination will make it possible to promote the curing of the epoxy resin and allow it to cure in a short time. There are no particular limitations on the curing accelerator (E), and useful examples include imidazoles, multivalent phenols, acid anhydrides, amines, hydrazides, polymercaptans, Lewis acid-amine complexes, and latent curing agents. Of these, imidazoles, multivalent phenols, and latent curing accelerators are preferred because they are high in storage stability and serve to give a cured product with high heat resistance. They may be used singly or as a mixture of two or more thereof.

Useful imidazoles include Curezol (registered trademark) 2MZ, Curezol (registered trademark) 2PZ, Curezol (registered trademark) 2MZ-A, and Curezol (registered trademark) 2MZ-OK (all trade names, manufactured by Shikoku Chemicals Corporation industry). Useful multivalent phenols include Sumilite Resin (registered trademark) PR-HF3, Sumilite Resin (registered trademark) PR-HF6 (both trade names, manufactured by Sumitomo Bakelite Co., Ltd.), Kayahard (registered trademark) KTG-105, Kayahard (registered trademark) NHN (both trade names, manufactured by Nippon Kayaku Co., Ltd.), Phenolite (registered trademark) TD2131, Phenolite (registered trademark) TD2090, Phenolite (registered trademark) VH-4150, Phenolite (registered trademark) KH-6021, Phenolite (registered trademark) KA-1160, and Phenolite (registered trademark) KA-1165 (all trade names, manufactured by DIC Corporation). Useful latent curing accelerators include dicyandiamide type latent curing agents, amine adduct type latent curing agents, organic acid hydrazide type latent curing agents, aromatic sulfonium salt type latent curing agents, microcapsule type latent curing agents, and photocuring type latent curing agents.

Useful dicyandiamide type latent curing agents include DICY7, DICY15, DICY50 (all trade names, manufactured by Japan Epoxy Resin Co., Ltd.), Amicure (registered trademark) AH-154, and Amicure (registered trademark) AH-162 (both trade names, manufactured by Ajinomoto Fine-Techno Co., Inc.). Useful amine adduct type latent curing agents include Amicure (registered trademark) PN-23, Amicure (registered trademark) PN-40, Amicure (registered trademark) MY-24, Amicure (registered trademark) MY-H (all trade names, manufactured byAjinomoto Fine-Techno Co., Inc.), and Fujicure (registered trademark) FXR-1030 (trade name, Fuji Kasei Kogyo Co., Ltd.). Useful organic acid hydrazide type latent curing agents include Amicure (registered trademark) VDH and Amicure (registered trademark) UDH (both trade names, manufactured by Ajinomoto Fine-Techno Co., Inc.). Useful aromatic sulfonium salt type latent curing agents include SAN-AID (registered trademark) S100, SAN-AID (registered trademark) SIl150, SAN-AID (registered trademark) SI180, SAN-AID (registered trademark) SI-B3, and SAN-AID (registered trademark) SI-B4 (all trade names, manufactured by Sanshin Chemical Industry Co., Ltd.). Useful microcapsule type latent curing agents include the curing agents listed above that are encapsulated in a vinyl compound, urea compound, or thermoplastic resin. In particular, examples of a microcapsule type latent curing agent produced by treating an amine adduct type latent curing agent with an isocyanate include Novacure (registered trademark) HX-3941 HP, Novacure (registered trademark) HXA3922HP, Novacure (registered trademark) HXA3932HP, and Novacure (registered trademark) HXA3042HP (all trade names, manufactured by Asahi Kasei Chemicals Corporation). In addition, useful photocuring type latent curing agents include OPTOMER (registered trademark) SP and OPTOMER (registered trademark) CP (manufactured by Adeka Corporation).

The content of the cure accelerating agent (E) is not particularly limited, but it is preferably 0.1 part by weight or more and 35 parts by weight or less relative to 100 parts by weight of the epoxy resin (D).

The thermosetting resin composition according to the present invention may contain an organic peroxide. If an organic peroxide is contained, it works to accelerate the curing of the phenylene ether resin (B) that contains a vinyl group and the maleimide resin (C), thereby ensuring increased mechanical strength and heat resistance. Examples of such an organic peroxide include benzoyl peroxide, cumene hydroperoxide, dicumyl peroxide, diisopropylbenzene hydroperoxide, t-butyl hydroperoxide, t-butylperoxy acetate, t-butylperoxy benzoate, t-butylisopropyl carbonate, di-t-butyl peroxide, t-butyl peroctate, 1,1-bis(t-butylperoxy)-3,3,5-trimethyl cyclohexane, 1,1-bis(t-butylperoxy) cyclohexane, and t-butylperoxy-2-ethyl hexanoate. The content of the organic peroxide is preferably 0.1 part by weight or more and 35 parts by weight or less relative to 100 parts by weight of the phenylene ether resin (B) that contains a vinyl group and the maleimide resin (C).

The thermosetting resin composition according to the present invention may contain inorganic particles if necessary. If inorganic particles are contained, they serve to ensure improved physical properties of the resin composition such as decreased thermal expansion coefficient during heat-curing. Useful materials for such inorganic particles include silica, hollow silica, alumina, titania, silicon nitride, boron nitride, aluminum nitride, iron oxide, and glass, as well as other metal oxides, metal nitrides, metal carbonates, and metal sulfates such as barium sulfate, which may be used singly or as a mixture of two or more thereof. Of these, silica can be used suitably because it is low in thermal expansion, high in heat dissipation, and low in hygroscopicity. Hollow silica can also be used suitably because it is low in dissipation factor.

When inorganic particles are contained in the thermosetting resin composition according to the present invention, they preferably account for 10 wt % or more and 90 wt % or less of the total quantity, which accounts for 100 wt %, of the resin composition. From the viewpoint of allowing the resin composition to be low in thermal expansion, high in heat diffusion, low in hygroscopicity, low in dielectric constant, and low in dissipation factor, it is preferable for the inorganic particles to account for 10 wt % more, and more preferably 20 wt % or more. From the viewpoint of improving the thermocompression bonding to the substrate during heat-curing and increasing the mechanical strength after heat-curing, furthermore, it is more preferable for the inorganic particles to account for 90 wt % or less, and more preferably 80 wt % or less. It is preferable for the inorganic particles to have an average particle diameter of 0.1 μm or more and 10 μm or less. From the viewpoint of decreasing the thermal expansion and improving the thermal diffusion of the resin composition, it is preferably 0.1 μm or more, and more preferably 0.5 μm or more. On the other hand, from the viewpoint of providing a thermosetting resin sheet with a smooth surface, it is preferably 10 μm or less, and more preferably 5 μm or less.

The thermosetting resin composition according to the present invention may contain a surfactant as required to ensure improved wettability on the substrate.

The thermosetting resin composition according to the present invention preferably contains a silane coupling agent (F). It is particularly preferable that a silane coupling agent as represented by the formula (12) be contained.

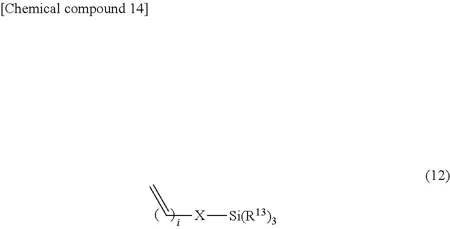

In the formula (12), X is an aliphatic or aromatic divalent hydrocarbon group containing 1 to 30 carbon atoms or a single bond; the R¹³ groups may be identical to or different from each other and are each a halogen atom, an alkyl group containing 1 to 6 carbon atoms, an alkoxy group containing 1 to 6 carbon atoms, a phenyl group, a hydroxyl group, or a phenoxy group; and i is an integer number of 1 to 3. Of the plurality of R¹³ groups, however, at least one is a halogen atom or an alkoxy group containing 1 to 6 carbon atoms.

Examples of such a silane coupling agent include trimethoxyaminopropylsilane, trimethoxycyclohexylepoxyethylsilane, trimethoxyvinylsilane, triethoxyvinylsilane, trimethoxythiolpropylsilane, trimethoxyglycidyloxypropylsilane, tris-(trimethoxysilylpropyl)isocyanurate, triethoxyaminopropylsilane, 3-methacryloxypropyltrimethoxysilane, 3-acryloxypropyltrimethoxysilane, p-styryltrimethoxysilane, and reaction products of trimethoxyaminopropylsilane and acid anhydrides, of which trimethoxyvinylsilane, triethoxyvinylsilane, 3-methacryloxypropyltrimethoxysilane, 3-acryloxypropyltrimethoxysilane, and p-styryltrimethoxysilane are preferable, and p-styryltrimethoxysilane is more preferable.

The content of the silane coupling agent (F) is not particularly limited, but it is preferably 0.01 wt % or more and 10 wt % or less, and more preferably 0.5 wt % or more and 5 wt % or less, of the total quantity, which account for 100 wt %, of the thermosetting resin composition. If it is 0.01 wt % or more, it serves to increase the adhesion to the substrate. If it is 10 wt % or less, it serves to improve the storage stability. The above examples of the silane coupling agent (F) may be used singly or as a mixture of two or more thereof. In addition, 0.5 to 10 wt % of an titanium chelating agent may also be contained in the resin composition.

Described next is the thermosetting resin sheet according to the present invention, which is prepared by laying the thermosetting resin composition according to the present invention in a non-heat-cured state over a support to form a layer. The thermosetting resin sheet according to the present invention in the above state can be used as an adhesive sheet. To process the thermosetting resin composition according to the present invention into a sheet, a good procedure is, for example, to prepare a varnish by mixing the resin composition in a solvent, spread it over a support film, and dry it to provide a sheet.

For this operation, any appropriate solvent may be used as long as it can dissolve the above components, and good examples include ketone based solvents such as acetone, methylethylketone, methylisobutylketone, cyclopentanone, and cyclohexanone; ether based solvents such as 1,4-dioxane, tetrahydrofuran, and diglyme; glycol ether based solvents such as methylcellosolve, ethylcellosolve, propyleneglycolmonomethylether, propyleneglycolmonoethylether, propyleneglycolmonobutylether, and diethyleneglycolmethylethylether; and others such as benzyl alcohol, propanol, N-methylpyrrolidone, γ-butyrolactone, ethylacetate, and N,N-dimethylformamide. In particular, if a solvent having a boiling point of 120° C. or less under atmospheric pressure is contained, the solvent can be removed in a short time at a low temperature, allowing a sheet to be produced easily.

The method to be used to prepare a varnish of an adhesive composition is not particularly limited, but it is preferable to mix the polyimide resin, the phenylene ether resin (B), the maleimide resin (C), and other components to be added as required in a solvent as listed above using a propeller stirrer, homogenizer, kneading machine, or the like, followed by mixing in a bead mill, ball mill, triple roll mill, or the like, as required from the viewpoint of increasing the dispersibility of the inorganic particles.

Good methods to spread a varnish over a support film include spincoat using a spinner, spray coating, roll coating, screen printing, and coating techniques using a blade coater, die coater, calender coater, meniscus coater, bar coater, roll coater, comma roll coater, gravure coater, screen coater, slit die coater, or the like.

Useful coating tools include roll coater, comma roll coater, gravure coater, screen coater, and slit die coater, of which the use of a slit die coater is preferred because of a smaller volatilization of the solvent during coating to ensure stable coatability. The thickness of the sheet prepared from a thermosetting resin composition, that is, the thermosetting resin sheet, is not particularly limited, but it is preferably in the range of 10 to 400 μm from the viewpoint of ensuring easiness of embedding in a circuit board with an irregular surface and good insulating properties.

Drying can be carried out by using an oven, hot plate, infrared ray, or the like. The drying temperature and drying period may be set appropriately as long as the organic solvent can be volatilized, and it is preferable to set them in appropriate ranges so that an adhesive sheet in an uncured or semicured state (B stage state) is formed. Specifically, it is preferable to maintain a temperature in the range of 40° C. to 120° C. for 1 minute to several tens of minutes. It may also be good to adopt a combination of temperatures in this range to perform heating in stages. For example, heat treatment may be performed at 70° C., 80° C., and 90° C. for 1 minute at each of the temperatures.

The support film to be used is not particularly limited, and various commonly available commercial films such as polyethylene terephthalate (PET) film, polyphenylene sulfide film, and polyimide film can be used.

The surface of the support film to be brought into contact with the adhesive composition may be surface-treated with silicone, silane coupling agent, aluminum chelating agent, polyurea, or the like in order to ensure strong contact and easy peeling. The thickness of the support film is not particularly limited, but it is preferably in the range of 10 to 100 μm from the viewpoint of workability.

In addition, the thermosetting resin sheet may also have a protective film to protect the surface. This serves to protect the adhesion sheet surface from contaminants such as dirt and dust in the air.

Such protective films include polyethylene film, polypropylene (PP) film, and polyester film. It is preferable for such a protective film to be weakly adhered to the adhesive sheet.

Next, methods for adhering substrates and members using the thermosetting resin composition or thermosetting resin sheet according to the present invention are described below with reference to examples. The resin composition is preferably used in the form of varnish as described above. First, using a resin composition varnish, a resin composition coat film is formed on a printed circuit board that is composed mainly of a glass substrate, glass epoxy substrate, etc., and a wiring layer formed thereon. Useful coating methods for applying the resin composition varnish include spincoat using a spinner, spray coating, roll coating, and screen printing. Although the required thickness of a coating film varies depending on the coating technique used, the solid content and viscosity of the resin composition, and the like, it is commonly preferable for the composition to be applied so that the film thickness after drying will be 10 μm or more and 400 μm or less. Next, the substrate coated with the resin composition varnish is dried to form a resin composition coat film. Drying can be carried out by using an oven, hot plate, infrared ray, or the like. The drying temperature and drying period may be set as desired as long as the organic solvent can be volatilized, and it is preferable to set them in appropriate ranges so that a resin composition coat film in an uncured or semicured state is formed. Specifically, it is preferable to maintain a temperature in the range of 50° C. to 150° C. for 1 minute to several hours.

On the other hand, if the thermosetting resin sheet has a protective film, it is peeled first, and then the thermosetting resin sheet and the printed circuit board are combined face-to-face and adhered by thermocompression bonding. Thermocompression bonding can be carried out by hot pressing treatment, thermal lamination treatment, thermal vacuum lamination treatment, or the like. The bonding temperature is preferably 40° C. or more from the viewpoint of the adhesion to the substrate and embedding property. On the other hand, the bonding temperature is preferably 250° C. or less because if the temperature is high during the bonding step, the thermosetting resin sheet will cure rapidly to deteriorate the workability. In the case where the thermosetting resin sheet has a support film, the support film may be peeled before the bonding step, or at an appropriate point in the thermocompression bonding step, or after the thermocompression bonding step.

The printed circuit board coated with a resin composition coat film obtained in this way is then thermocompression-bonded to a resin film of polyimide, liquid crystal polymer, etc., a printed circuit board, or other such members. The thermocompression bonding temperature is at least not lower than the glass transition temperature of the resin and is preferably in the temperature range of 100° C. to 400° C. Furthermore, the pressure used for pressure bonding is preferably in the range of 0.01 to 10 MPa. It is maintained preferably for 1 second to several minutes.

After the thermocompression bonding step, the film is cured by heating at a temperature of 120° C. to 400° C. to produce a cured film. This heat treatment is performed for 5 minutes to 5 hours by stepwise heating at selected temperatures or continuous heating-up over a certain selected temperature range. For example, heat treatment may be performed at 130° C. and 200° C. for 30 minutes at each temperature. Alternatively, heating may be performed for 2 hours while linearly increasing the temperature from room temperature to 250° C. In these steps, it is preferable for the heating temperature to be 150° C. or more and 300° C. or less, and more preferably 180° C. or more and 250° C. or less. The bonded body obtained in this way by thermocompression bonding preferably has a peel strength of 4 N/cm or more from the viewpoint of ensuring reliable adhesion. It is more preferably 6 N/cm or more.

The cured film obtained in this way by thermocompression bonding preferably has a glass transition temperature (Tg) of 100° C. or more from the viewpoint of passing reliability test of semiconductor devices. It is more preferably 120° C. or more. In addition, the resulting cured film preferably has a dielectric constant of 3.0 or less at 10 GHz from the viewpoint of decreasing the dielectric loss of electric signals. It is more preferably 2.8 or less. Similarly, the resulting cured film preferably has a dissipation factor of 0.01 or less at 10 GHz from the viewpoint of decreasing the dielectric loss of electric signals. It is more preferably 0.008 or less. The thickness of the cured film may be set to any desired value, but it is preferably in the range of 10 μm or more and 400 μm or less.

The cured film according to the present invention can be be produced by curing a thermosetting resin composition or a thermosetting resin sheet by heat treatment. The heat treatment temperature is only required to be at least in the range of 150° C. to 350° C. For example, it is performed for 5 minutes to 5 hours by stepwise heating at selected temperatures or continuous heating-up over a certain selected temperature range. As an example, heat treatment is performed at 130° C. and 200° C. for 30 minutes at each temperature. As a curing condition for the present invention, the lower temperature limit is preferably 170° C. or more, but it is more preferably 180° C. or more to ensure a sufficient degree of curing. For the curing conditions, the upper limit is not particularly limited, but it is preferably 280° C. or less, more preferably 250° C. or less, and still more preferably 230° C. or less from the viewpoint of suppressing film shrinkage and stress increase.

The electronic component according to present invention is an electronic component that includes a cured product produced by heat-curing the thermosetting resin composition or the thermosetting resin sheet according to the present invention. Furthermore, it is more preferably an electronic component attached to an adherend.

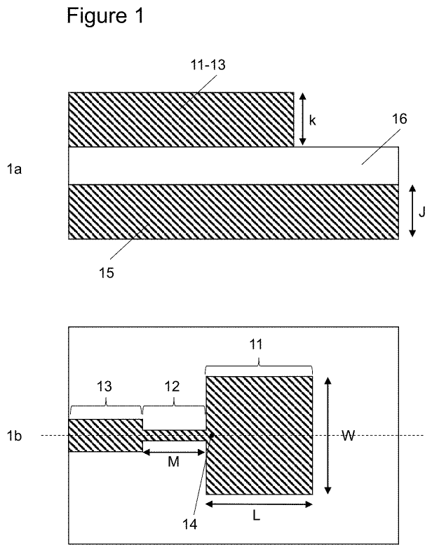

Described next is an antenna element that includes a cured film produced by curing the thermosetting resin composition according to the present invention. FIG. 1 is a schematic diagram of a coplanar waveguide-fed microstrip antenna, which is a kind of planar antenna. The diagram 1a is a cross-sectional view and 1b is a top view. The production method is described first. The thermosetting resin composition according to the present invention is spread over a copper foil sheet and prebaked, or an uncured sheet of the thermosetting resin is laminated with a copper foil sheet. Then, after the lamination with copper foil sheets, it is heat-cured to form a cured film with both sides coated with copper foil sheets. Subsequently, patterning is performed by the subtraction method to form an antenna element with a copper wiring antenna pattern having a microstrip line (MSL) as illustrated in FIG. 1.

Described next is the antenna pattern shown in FIG. 1. In the diagram 1a, 15 denotes the ground (overall) and 16 denotes the insulating film that works as the substrate of the antenna. The layer 11 to 13 located above shows the cross section of the antenna wiring formed in the aforementioned patterning step. The ground wiring thickness J and the antenna wiring thickness K can be set as desired depending on impedance design, but they are commonly in the range of 2 to 20 μm. In the diagram 1b, 11 is the antenna part; 12 is the matching circuit; 13 is the MSL feeder line; and 14 is the feeding point. To adjust the impedance matching between the antenna part 11 and the MSL feeder line 13, the length M of the matching circuit 12 is equal to ¼ λr (λr=(wavelength of transmitted wave)/(insulation material's dielectric constant)^{1/2}). Furthermore, the width W and length L of the antenna part 11 are designed to ½ λr. The length L of the antenna part may be less than ½ λr depending on impedance design. The cured film according to the present invention is low in dielectric constant and low in dissipation factor, and this serves to provide an antenna element with a high efficiency and high gain. Due to these characteristics, furthermore, an antenna element incorporating the insulation film according to the present invention will work as an antenna suitable for high frequency applications, and it will be possible to produce a small antenna element by decreasing the antenna part size to an area (L×W) of 1,000 mm² or less. In this way, a small, high frequency antenna element with a high efficiency and high gain can be produced.

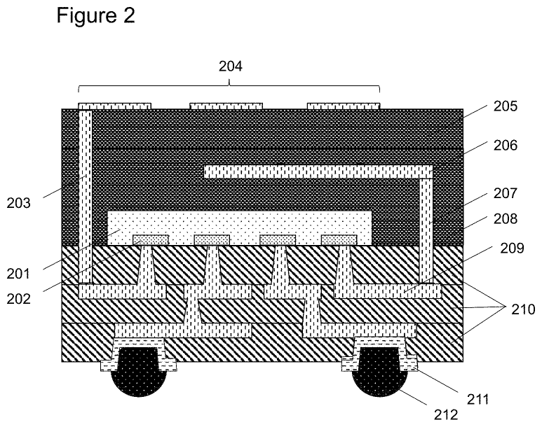

Described next is a semiconductor package that contains an IC chip (semiconductor element), a redistribution layer, molding resin layers, and an antenna wiring layers. FIG. 2 is a schematic diagram showing a cross section of a semiconductor package that contains an IC chip (semiconductor element), redistribution layers, molding resin layers, and an antenna element. On the electrode pad 202 of an IC chip 201, there is a redistribution layer (two copper layers and three insulation film layers) that includes copper wiring layers 209 and insulation films 210 made of the cured film according to the present invention. The pad for the redistribution layer (copper layers 209 and insulation films 210) has barrier metal members 211 and solder bumps 212. To mold the IC chip, the first molding resin layer 208 is formed using the cured film according to the present invention, and copper wiring layers 209 that work for grounding the antenna is located on top thereof. Through a viahole formed in the first molding resin layer 208, a first via wire 207 runs to make a connection between the ground 206 and the redistribution layer (copper wiring layers 209 and insulation films 210). On the first molding resin layer 208 and the ground 206, a second molding resin 205 is formed using the cured film according to the present invention, and a planar antenna wiring 204 is formed on top thereof. Through a viahole formed in the first molding resin 208 and the second molding resin 205, a second via wiring 203 is formed to achieve connection between the planar antenna wiring 204 and the redistribution layers (copper wiring layers 209 and insulation films 210). It is preferable for each of the insulation films 210 to have a thickness of 10 to 20 μm, and it is preferable for the first molding resin layer and the second molding resin layer to have a thickness of 50 to 200 μm and 100 to 400 μm, respectively. Since the cured film according to the present invention is low in dielectric constant and low in dissipation factor, a semiconductor package including the resulting antenna element is high in efficiency and high in gain, leading to a small transmittance loss in the package.

Thus, it is preferable for the electronic component according to present invention to be an electronic component including an antenna element having at least one antenna wiring layer and the cured film according to the present invention wherein: the antenna wiring layer contains at least one or more selected from the group consisting of meander type loop antenna, coil type loop antenna, meander type monopole antenna, meander type dipole antenna, and microstrip antenna; each antenna part in the antenna wiring layer has an exclusive area of 1,000 mm² or less; and the cured film is an insulation film for insulation between the ground and the antenna wiring layer.

In addition, it is preferable for the electronic component according to present invention to be an electronic component including a semiconductor package having at least a semiconductor element, redistribution layer, molding resin layers, and antenna wiring wherein: the insulating layers in the redistribution layer and/or the molding resin layers contain the cured film according to the present invention and the molding resin is located between the ground and the antenna wiring layer.

Furthermore, it is preferable for the electronic component according to present invention to be an electronic component including an antenna element in the form of a stack of an antenna wiring layer and the cured film according to the present invention wherein: the antenna wiring layer has a height of 50 to 200 μm and the cured film has a thickness of 80 to 300 μm. A stack of an antenna wiring layer and the cured film in which the antenna wiring layer and the cured film have a height and a thickness in the aforementioned ranges can perform transmission and reception of signals over a wide range in spite of a small size and provide an antenna element with a high efficiency and a high gain because the cured film according to the present invention is low in dielectric constant and low in dissipation factor.

The electronic device according to the present invention is an electronic device including the electronic component according to present invention. Applications of the resin composition according to the present invention, including the above, are described below with reference to examples, but it should be understood that applications of the resin composition according to the present invention are not limited thereto.

The thermosetting resin composition according to the present invention can be widely used as adhesives and insulation resin for semiconductor devices and in particular will be used suitably in RF modules incorporated in high speed, large-capacity radio communication instruments for electric signal processing such as portable terminals and in on-board millimeter wave radars for automobiles. A RF module is a multifunctional device used in a radio communication apparatus and it is in the form of a module containing a plurality of IC chips and passive components (SAW filter, capacitor, resistance, coil, etc.) mounted on a substrate. Such a substrate carrying passive components mounted thereon has a multi-layered structure containing insulating layers and copper wiring layers, and the thermosetting resin composition according to the present invention can serve suitably to produce these insulating layers. A thermosetting resin sheet is adhered to a printed circuit board, or a resin composition varnish is applied and dried to form an insulating layer. Subsequently, a copper wiring layer is formed by electroplating on the surface of the insulating layer, and a thermosetting resin sheet is adhered thereon or a resin composition varnish is spread thereon to form a multi-layered substrate. Here, a semiconductor device as referred to for the present invention means any device that can function by making use of characteristics of a semiconductor element, and such devices include those containing a semiconductor element connected to a substrate and those containing semiconductor elements connected to each other or containing substrates connected to each other, and more specifically, electrooptical devices, semiconductor circuit boards, and electronic components containing them are all included in the category of semiconductor devices. Thus, the electronic component according to present invention has good characteristics at high frequencies and can be used suitably in the electronic device according to the present invention, which is required to work with high operational reliability at high frequencies.

### EXAMPLES

The present invention will now be illustrated in detail with reference to Examples, though the invention is not limited thereto. First, materials referred to by abbreviations in the Examples are described in detail below.

<Polyimide Resin Materials>

BSAA: 2,2′-bis[4-(3,4-dicarboxyphenoxy)phenyl]propane dianhydride

TBIS-DMPN: 5-isobenzofurancarboxylic acid, 1,3-dihydro-1,3-dioxo-5,5′-[cyclododecylidene-bis(2-methyl-4,1-phenylene)] ester (manufactured by Taoka Chemical Co., Ltd.)

ODPA: 4,4′-oxydiphthalic dianhydride (manufactured by Manac Incorporated)

TFMB: 4,4′-diamino-2,2′-bis(trifluoromethyl)biphenyl (manufactured by Wakayama Seika Kogyo Co., Ltd.)

mTB: 4,4′-diamino-2,2′-dimethylbiphenyl (manufactured by Wakayama Seika Kogyo Co., Ltd.)

LP7100: bis(3-aminopropyl)tetramethyldisiloxane (manufactured by Shin-Etsu Chemical Co., Ltd.)

X-22-9409: diaminopolysiloxane (amine equivalent: 670) (manufactured by Shin-Etsu Chemical Co., Ltd.)

X-22-1660B-3: diaminopolysiloxane (amine equivalent: 2,170) (manufactured by Shin-Etsu Chemical Co., Ltd.)

Versamine 551: a dimer diamine compound containing a compound as represented by the formula (11) (trade name, manufactured by BASF) (average amine value: 205) Priamine 1075: a dimer diamine compound containing a compound as represented by the formula (10) (trade name, manufactured by Croda Japan K.K.) (average amine value: 205)

<Phenylene Ether Resin (B)>

OPE-2st-1200: oligophenylene ether (molecular chain end: vinyl group) (number average molecular weight: 1,200) (manufactured by Mitsubishi Gas Chemical Co., Inc.)

OPE-2st-2200: oligophenylene ether (molecular chain end: vinyl group) (number average molecular weight: 2,200) (manufactured by Mitsubishi Gas Chemical Co., Inc.)

SA-90: low molecular weight polyphenylene ether (molecular chain end: phenolic hydroxyl group) (number average molecular weight: 1,700) (SABIC Japan Llc.)

<Maleimide Resin>

BMI-4000: 2,2′-bis[4-(4-maleimidephenoxy)phenyl]propane (manufactured by Daiwa Fine Chemicals Co., Ltd.)

MIR-3000-70MT: biphenylaralkyl based maleimide compound (manufactured by Nippon Kayaku Co., Ltd.)

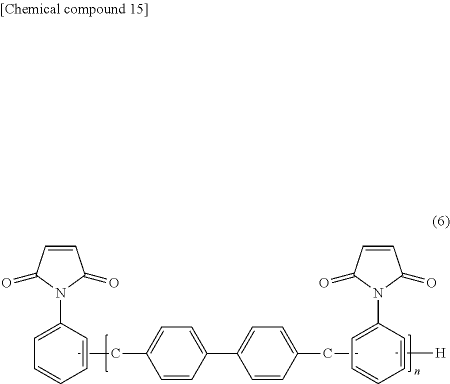

<Epoxy Resin (D)>

JER828: bisphenol A type liquid epoxy resin (manufactured by Mitsubishi Chemical Corporation)

E101: branched alkyl group-containing epoxy resin (manufactured by Nissan Chemical Industries, Ltd.)

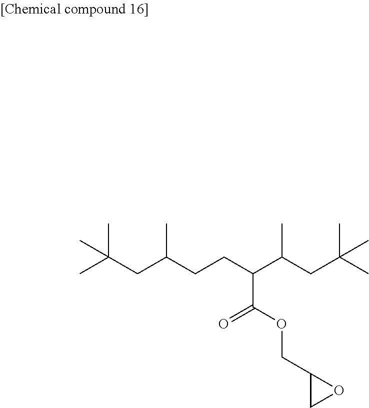 [SMILES: CC(CCC(C(=O)OCC1CO1)C(C)CC(C)(C)C)CC(C)(C)C]

TEPIC-FL: isocyanuric acid-modified epoxy resin (manufactured by Nissan Chemical Industries, Ltd.)

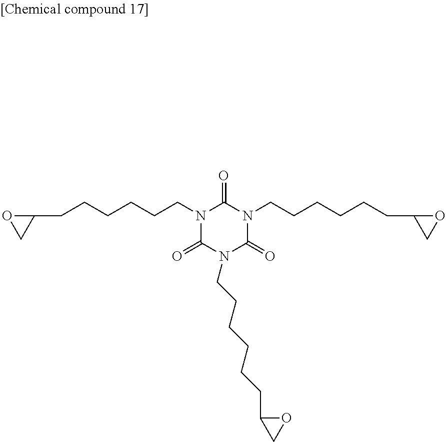 [SMILES: O=c1n(CCCCCCC2CO2)c(=O)n(CCCCCCC2CO2)c(=O)n1CCCCCCC1CO1]

<Curing Accelerator (E)>

2P4MZ: 2-phenyl-4-methylimidazole

SI-150: dimethyl-p-acetoxyphenylsulfonium=hexafluoroantimonate (manufactured by Sanshin Chemical Industry Co., Ltd.)

<Organic Peroxide>

DCP: dicumylperoxide (manufactured by NOF Corporation)

<Adhesion Improver>

KBM1003: vinyltrimethoxysilane (manufactured by Shin-Etsu Chemical Co., Ltd.)

KBM1403: p-styryltrimethoxysilane (manufactured by Shin-Etsu Chemical Co., Ltd.)

<Solvent>

γBL: γ-butyrolactone

The evaluation methods used in each Example and Comparative example are described below.

<Tg of Polyimide Resin Synthesized>

A polyimide resin was dissolved in γBL to prepare a solution with a solid content of 30 wt % and it was spread over copper foil with a thickness of 18 μm and dried in an oven under the conditions of 100° C.×30 min, 120° C.×30 min, or 180° C.×30 min. The spreading of the polyimide resin was performed in such a manner that its thickness would be 50 μm after drying. Each layered body prepared in this way was etched with an aqueous ferric chloride solution to remove the copper foil to provide a polyimide film. The polyimide film was cut to a size of 5 mm×30 mm and examined by a dynamic viscoelasticity measuring apparatus (DVA-200, manufactured by IT Keisokuseigyo Kabushiki Kaisha) at a heating rate of 5° C./min and a frequency of 1 Hz. The temperature at which tan b reached a peak value was adopted as Tg.

<Number Average Molecular Weight of Phenylene Ether Resin (B)>

The phenylene ether resin (B) was dissolved in tetrahydrofuran (hereinafter referred to as THF) to prepare a solution with a solid content of 0.1 wt % and its weight average molecular weight in terms of polystyrene was measured using a GPC apparatus, Waters 2690 (manufactured by Nihon Waters K.K.) set up as described below. The GPC measuring conditions included the use of THE as mobile phase and a developing speed of 0.4 ml/min.

Detector: Waters 996

System controller: Waters 2690

Column oven: Waters HTR-B

Thermocontroller: Waters TCM

Column: TOSOH grArd comn

Column: TOSOH TSK-GEL α-2500H

Column: TOSOH TSK-GEL α-4000H

<Weight Average Molecular Weight of Polyimide Resin Synthesized>

A polyimide resin was dissolved in N-methyl-2-pyrrolidone (hereinafter referred to as NMP) to prepare a solution with a solid content of 0.1 wt % and its weight average molecular weight in terms of polystyrene was measured using a GPC apparatus, Waters 2690 (manufactured by Nihon Waters K.K.) set up as described below. The GPC measuring conditions included the use of a NMP solution containing 0.05 mole/I each of LiCl and phosphoric acid as mobile phase and a developing speed of 0.4 ml/min.

Detector: Waters 996

System controller: Waters 2690

Column oven: Waters HTR-B

Thermocontroller: Waters TCM

Column: TOSOH grArd comn

Column: TOSOH TSK-GEL α-4000

Column: TOSOH TSK-GEL α-2500

<Imidization Rate of Polyimide Resin Synthesized>

First, an infrared absorption spectrum of a polymer is measured and the existence of absorption peaks attributed to the imide structure in polyimide (near 1,780 cm⁻¹ and 1,377 cm⁻¹) was confirmed. Then, the polymer was heat-treated at 350° C. for 1 hour and an infrared absorption spectrum was measured again, followed by comparing the peak strength near 1,377 cm⁻¹ determined before heat treatment and that after heat treatment. The imidization rate of the polymer before heat treatment relative to the imidization rate of the polymer after heat treatment, which is defined as 100%, was determined.

<Adhesion Strength of Copper Foil>

The resin composition prepared in each Example and Comparative example was spread over a support film, namely a PET film with a thickness of 38 μm, using a comma roll coater, dried at 100° C. for 30 minutes, and laminated with a protective film, namely a PP film with a thickness of 10 μm, to provide an adhesive sheet. The spreading step was performed in such a manner that the thermosetting resin sheet in the adhesive sheet had a film thickness of 50 μm. Subsequently, the protective film was peeled and the exposed surface was pressed against copperfoil (NA-VLP, thickness 15 μm, manufactured by Mitsui Mining & Smelting Co., Ltd.) in a hot plate press machine at a pressing temperature of 120° C. under a pressure of 1 MPA for a pressing period of 5 minutes. Then, after removing the support film, another copper foil sheet was laid on the resin composition and pressed at a pressing temperature 180° C. under a pressure of 1 MPA for a pressing period of 10 minutes. This is followed by heat-curing at 180° C. for 1 hour in a hot air circulation type dryer. Only one side of the layered body produced in this way was etched with an aqueous ferric chloride solution to remove the copper foil to form a circuit with a line width of 2 mm. Then, the 2 mm wide copper foil line was lifted up and pulled with a push gel gauge in the direction of 90° C. to the layered body to measure the adhesion strength.

<Soldering Heat Resistance>

A layered plate (copper foil 15 μm/resin 50 μm/copper foil 15 μm) prepared in the same procedure as described above was cut to a size of 50 mm×50 mm and dipped for 2 minutes in a bath of molten solder heated at 260° C. After the dipping step, it was rated as good if it was free of copper foil peeling or foaming and suffered no changes from the initial state whereas it was rated as inferior if it suffered peeling or foaming.

<Tg>

From the layered body produced by the procedure described above, copper foil was removed by etching with an aqueous ferric chloride solution to provide a cured product. It was cut to 5 mm width×30 mm and examined in the range of −50° C. to 300° C. using an dynamic viscoelasticity measuring apparatus (DVA-200, manufactured by IT Keisokuseigyo Kabushiki Kaisha) under the conditions of a clamp-to-clamp distance of 15 mm, heating rate of 5° C./min, and frequency of 1 Hz, and the temperature at which tan b reached a peak value was adopted as Tg.

<Relative Dielectric Constant and Dissipation Factor>

A cured product of a thermosetting resin sheet prepared by the same procedure as described above was cut to 60×100 mm and moisture-conditioned in a 22° C./60% RH atmosphere for 24 hours. The relative dielectric constant and dissipation factor were measured using a cylindrical cavity resonator. Vector Network Analyzer HP8510C, manufactured by Agilent Technologies, was used to take measurements at a frequency of 10 GHz in a 22° C./60% RH environment.

### Example 1

In a 300 ml four neck flask equipped with a stirrer, thermometer, nitrogen supply tube, and dropping funnel, 112.47 g of γBL and 31.21 g of BSAA were fed and dissolved by stirring at 60° C. in a nitrogen atmosphere. Then, while stirring at 60° C., 9.61 g of TFMB and 7.46 g of LP7100 were added and stirred for 1 hour. Subsequently, the temperature was raised by heating to 180° C. and stirring was performed for 3 hours, followed by cooling to room temperature to prepare a polyimide solution A (solid content 30.0 wt %). The weight average molecular weight of the polyimide was measured to be 36,400, and its Tg and imidization rate were measured to be 125° C. and 100%, respectively.

To 12.0 g of the polyimide solution A (solid content 3.6 g) prepared by the procedure described above, 1.54 g (solid content 1.0 g) of OPE-2st-1200 (solid content 65 wt %, toluene solution), 0.2 g of BMI4000, 1.2 g of TEPIC-FL, and 0.06 g of 2P4MZ were added and mixed by stirring to provide a resin composition. The resulting resin composition was examined by the procedure described above to measure the copper foil adhesion strength, soldering heat resistance, Tg, relative dielectric constant, and dissipation factor.

### Example 2

In a 300 ml four neck flask equipped with a stirrer, thermometer, nitrogen supply tube, and dropping funnel, 141.64 g of γBL and 43.73 g of TBIS-DMPN were fed and dissolved by stirring at 60° C. in a nitrogen atmosphere. Then, while stirring at 60° C., 9.61 g of TFMB and 7.46 g of LP7100 were added and stirred for 1 hour. Subsequently, the temperature was raised by heating to 180° C. and stirring was performed for 3 hours, followed by cooling to room temperature to prepare a polyimide solution B (solid content 30.0 wt %). The weight average molecular weight of the polyimide was measured to be 43,210, and its Tg and imidization rate were measured to be 168° C. and 100%, respectively.

A 12.0 g portion (solid content 3.6 g) of the polyimide solution B prepared in this way was mixed with the components listed in Table 2 by the same procedure as in Example 1 to provide a resin composition. The resulting resin composition was examined by the procedure described above to measure the copper foil adhesion strength, soldering heat resistance, Tg, relative dielectric constant, and dissipation factor.

### Example 3

In a 300 ml four neck flask equipped with a stirrer, thermometer, nitrogen supply tube, and dropping funnel, 82.05 g of γBL and 18.61 g of ODPA were fed and dissolved by stirring at 60° C. in a nitrogen atmosphere. Then, while stirring at 60° C., 9.61 g of TFMB and 7.46 g of LP7100 were added and stirred for 1 hour. Subsequently, the temperature was raised by heating to 180° C. and stirring was performed for 3 hours, followed by cooling to room temperature to prepare a polyimide solution B (solid content 30.0 wt %). The weight average molecular weight of the polyimide was measured to be 41,630, and its Tg and imidization rate were measured to be 178° C. and 100%, respectively.

A 12.0 g portion (solid content 3.6 g) of the polyimide solution C prepared in this way was mixed with the components listed in Table 2 by the same procedure as in Example 1 to provide a resin composition. The resulting resin composition was examined by the procedure described above to measure the copper foil adhesion strength, soldering heat resistance, Tg, relative dielectric constant, and dissipation factor.

### Example 4

In a 500 ml four neck flask equipped with a stirrer, thermometer, nitrogen supply tube, and dropping funnel, 215.43 g of γBL and 43.73 g of TBIS-DMPN were fed and dissolved by stirring at 60° C. in a nitrogen atmosphere. Then, while stirring at 60° C., 9.61 g of TFMB and 40.20 g of X-22-9409 were added and stirred for 1 hour. Subsequently, the temperature was raised by heating to 180° C. and stirring was performed for 3 hours, followed by cooling to room temperature to prepare a polyimide solution D (solid content 30.0 wt %). The weight average molecular weight of the polyimide was measured to be 33,400, and its Tg and imidization rate were measured to be 65° C. and 100%, respectively.

A 12.0 g portion (solid content 3.6 g) of the polyimide solution D prepared in this way was mixed with the components listed in Table 2 by the same procedure as in Example 1 to provide a resin composition. The resulting resin composition was examined by the procedure described above to measure the copper foil adhesion strength, soldering heat resistance, Tg, relative dielectric constant, and dissipation factor.

### Example 5

In a 500 ml four neck flask equipped with a stirrer, thermometer, nitrogen supply tube, and dropping funnel, 211.06 g of γBL and 21.86 g of TBIS-DMPN were fed and dissolved by stirring at 60° C. in a nitrogen atmosphere. Then, while stirring at 60° C., 4.80 g of TFMB and 65.10 g of X-22-1660B-3 were added and stirred for 1 hour. Subsequently, the temperature was raised by heating to 180° C. and stirring was performed for 3 hours, followed by cooling to room temperature to prepare a polyimide solution E (solid content 30.0 wt %). The weight average molecular weight of the polyimide was measured to be 29,540, and its Tg and imidization rate were measured to be −5° C. and 100%, respectively.

A 12.0 g portion (solid content 3.6 g) of the polyimide solution E prepared in this way was mixed with the components listed in Table 2 by the same procedure as in Example 1 to provide a resin composition. The resulting resin composition was examined by the procedure described above to measure the copper foil adhesion strength, soldering heat resistance, Tg, relative dielectric constant, and dissipation factor.

### Example 6

In a 500 ml four neck flask equipped with a stirrer, thermometer, nitrogen supply tube, and dropping funnel, 142.99 g of γBL and 43.73 g of TBIS-DMPN were fed and dissolved by stirring at 60° C. in a nitrogen atmosphere. Then, while stirring at 60° C., 10.99 g of BAHF and 7.46 g of LP7100 were added and stirred for 1 hour. Subsequently, the temperature was raised by heating to 180° C. and stirring was performed for 3 hours, followed by cooling to room temperature to prepare a polyimide solution F (solid content 30.0 wt %). The weight average molecular weight of the polyimide was measured to be 28,580, and its Tg and imidization rate were measured to be 164° C. and 100%, respectively.

A 12.0 g portion (solid content 3.6 g) of the polyimide solution E prepared in this way was mixed with the components listed in Table 2 by the same procedure as in Example 1 to provide a resin composition. The resulting resin composition was examined by the procedure described above to measure the copper foil adhesion strength, soldering heat resistance, Tg, relative dielectric constant, and dissipation factor.

### Example 7

In a 500 ml four neck flask equipped with a stirrer, thermometer, nitrogen supply tube, and dropping funnel, 198.55 g of γBL and 65.59 g of TBIS-DMPN were fed and dissolved by stirring at 60° C. in a nitrogen atmosphere. Then, while stirring at 60° C., 9.55 g of mTB and 11.18 g of LP7100 were added and stirred for 1 hour. Subsequently, the temperature was raised by heating to 180° C. and stirring was performed for 3 hours, followed by cooling to room temperature to prepare a polyimide solution G (solid content 30.0 wt %). The weight average molecular weight of the polyimide was measured to be 44,590, and its Tg and imidization rate were measured to be 169° C. and 100%, respectively.

A 12.0 g portion (solid content 3.6 g) of the polyimide solution G prepared in this way was mixed with the components listed in Table 2 by the same procedure as in Example 1 to provide a resin composition. The resulting resin composition was examined by the procedure described above to measure the copper foil adhesion strength, soldering heat resistance, Tg, relative dielectric constant, and dissipation factor.

### Example 8

In a 300 ml four neck flask equipped with a stirrer, thermometer, nitrogen supply tube, and dropping funnel, 141.70 g of γBL and 31.02 g of ODPA were fed and dissolved by stirring at 60° C. in a nitrogen atmosphere. Then, while stirring at 60° C., 25.62 g of TFMB and 4.97 g of LP7100 were added and stirred for 1 hour. Subsequently, the temperature was raised by heating to 180° C. and stirring was performed for 3 hours, followed by cooling to room temperature to prepare a polyimide solution H (solid content 30.0 wt %). The weight average molecular weight of the polyimide was measured to be 43,200, and its Tg and imidization rate were measured to be 208° C. and 100%, respectively.

A 12.0 g portion (solid content 3.6 g) of the polyimide solution H prepared in this way was mixed with the components listed in Table 2 by the same procedure as in Example 1 to provide a resin composition. The resulting resin composition was examined by the procedure described above to measure the copper foil adhesion strength, soldering heat resistance, Tg, relative dielectric constant, and dissipation factor.

### Example 9

In a 300 ml four neck flask equipped with a stirrer, thermometer, nitrogen supply tube, and dropping funnel, 105.46 g of γBL and 26.02 g of BSAA were fed and dissolved by stirring at 60° C. in a nitrogen atmosphere. Then, while stirring at 60° C., 11.21 g of TFMB and 7.96 g of Versamine 551 were added and stirred for 1 hour. Subsequently, the temperature was raised by heating to 180° C. and stirring was performed for 3 hours, followed by cooling to room temperature to prepare a polyimide solution J (solid content 30.0 wt %). The weight average molecular weight of the polyimide was measured to be 32,100, and its Tg and imidization rate were measured to be 139° C. and 100%, respectively.

A 12.0 g portion (solid content 3.6 g) of the polyimide solution J prepared in this way was mixed with the components listed in Table 2 by the same procedure as in Example 1 to provide a resin composition. The resulting resin composition was examined by the procedure described above to measure the copper foil adhesion strength, soldering heat resistance, Tg, relative dielectric constant, and dissipation factor.

### Example 10

In a 300 ml four neck flask equipped with a stirrer, thermometer, nitrogen supply tube, and dropping funnel, 105.60 g of γBL and 26.02 g of BSAA were fed and dissolved by stirring at 60° C. in a nitrogen atmosphere. Then, while stirring at 60° C., 11.21 g of TFMB and 8.02 g of Priamine 1075 were added and stirred for 1 hour. Subsequently, the temperature was raised by heating to 180° C. and stirring was performed for 3 hours, followed by cooling to room temperature to prepare a polyimide solution K (solid content 30.0 wt %). The weight average molecular weight of the polyimide was measured to be 31,200, and its Tg and imidization rate were measured to be 134° C. and 100%, respectively.

A 12.0 g portion (solid content 3.6 g) of the polyimide solution K prepared in this way was mixed with the components listed in Table 2 by the same procedure as in Example 1 to provide a resin composition. The resulting resin composition was examined by the procedure described above to measure the copper foil adhesion strength, soldering heat resistance, Tg, relative dielectric constant, and dissipation factor.

### Example 11

In a 300 ml four neck flask equipped with a stirrer, thermometer, nitrogen supply tube, and dropping funnel, 101.84 g of γBL and 26.02 g of BSAA were fed and dissolved by stirring at 60° C. in a nitrogen atmosphere. Then, while stirring at 60° C., 13.61 g of TFMB and 4.01 g of Priamine 1075 were added and stirred for 1 hour. Subsequently, the temperature was raised by heating to 180° C. and stirring was performed for 3 hours, followed by cooling to room temperature to prepare a polyimide solution L (solid content 30.0 wt %). The weight average molecular weight of the polyimide was measured to be 36,800, and its Tg and imidization rate were measured to be 162° C. and 100%, respectively.

A 12.0 g portion (solid content 3.6 g) of the polyimide solution L prepared in this way was mixed with the components listed in Table 2 by the same procedure as in Example 1 to provide a resin composition. The resulting resin composition was examined by the procedure described above to measure the copper foil adhesion strength, soldering heat resistance, Tg, relative dielectric constant, and dissipation factor.

### Example 12

In a 300 ml four neck flask equipped with a stirrer, thermometer, nitrogen supply tube, and dropping funnel, 104.76 g of γBL and 26.02 g of BSAA were fed and dissolved by stirring at 60° C. in a nitrogen atmosphere. Then, while stirring at 60° C., 9.61 g of TFMB, 8.02 g of Priamine 1075, and 1.24 g of LP7100 were added and stirred for 1 hour. Subsequently, the temperature was raised by heating to 180° C. and stirring was performed for 3 hours, followed by cooling to room temperature to prepare a polyimide solution M (solid content 30.0 wt %). The weight average molecular weight of the polyimide was measured to be 30,100, and its Tg and imidization rate were measured to be 124° C. and 100%, respectively.

A 12.0 g portion (solid content 3.6 g) of the polyimide solution M prepared in this way was mixed with the components listed in Table 2 by the same procedure as in Example 1 to provide a resin composition. The resulting resin composition was examined by the procedure described above to measure the copper foil adhesion strength, soldering heat resistance, Tg, relative dielectric constant, and dissipation factor.

### Example 13

In a 300 ml four neck flask equipped with a stirrer, thermometer, nitrogen supply tube, and dropping funnel, 103.93 g of γBL and 26.02 g of BSAA were fed and dissolved by stirring at 60° C. in a nitrogen atmosphere. Then, while stirring at 60° C., 8.01 g of TFMB, 8.02 g of Priamine 1075, and 2.49 g of LP7100 were added and stirred for 1 hour. Subsequently, the temperature was raised by heating to 180° C. and stirring was performed for 3 hours, followed by cooling to room temperature to prepare a polyimide solution N (solid content 30.0 wt %). The weight average molecular weight of the polyimide was measured to be 28,200, and its Tg and imidization rate were measured to be 114° C. and 100%, respectively.

A 12.0 g portion (solid content 3.6 g) of the polyimide solution N prepared in this way was mixed with the components listed in Table 2 by the same procedure as in Example 1 to provide a resin composition. The resulting resin composition was examined by the procedure described above to measure the copper foil adhesion strength, soldering heat resistance, Tg, relative dielectric constant, and dissipation factor.

### Example 14

In a 300 ml four neck flask equipped with a stirrer, thermometer, nitrogen supply tube, and dropping funnel, 100.17 g of γBL and 26.02 g of BSAA were fed and dissolved by stirring at 60° C. in a nitrogen atmosphere. Then, while stirring at 60° C., 10.41 g of TFMB, 4.01 g of Priamine 1075, and 2.49 g of LP7100 were added and stirred for 1 hour. Subsequently, the temperature was raised by heating to 180° C. and stirring was performed for 3 hours, followed by cooling to room temperature to prepare a polyimide solution O (solid content 30.0 wt %). The weight average molecular weight of the polyimide was measured to be 29,800, and its Tg and imidization rate were measured to be 149° C. and 100%, respectively.

A 12.0 g portion (solid content 3.6 g) of the polyimide solution O prepared in this way was mixed with the components listed in Table 2 by the same procedure as in Example 1 to provide a resin composition. The resulting resin composition was examined by the procedure described above to measure the copper foil adhesion strength, soldering heat resistance, Tg, relative dielectric constant, and dissipation factor.

### Example 15

In a 300 ml four neck flask equipped with a stirrer, thermometer, nitrogen supply tube, and dropping funnel, 99.33 g of γBL and 26.02 g of BSAA were fed and dissolved by stirring at 60° C. in a nitrogen atmosphere. Then, while stirring at 60° C., 8.81 g of TFMB, 4.01 g of Priamine 1075, and 3.73 g of LP7100 were added and stirred for 1 hour. Subsequently, the temperature was raised by heating to 180° C. and stirring was performed for 3 hours, followed by cooling to room temperature to prepare a polyimide solution P (solid content 30.0 wt %). The weight average molecular weight of the polyimide was measured to be 29,100, and its Tg and imidization rate were measured to be 131° C. and 100%, respectively.

A 12.0 g portion (solid content 3.6 g) of the polyimide solution P prepared in this way was mixed with the components listed in Table 2 by the same procedure as in Example 1 to provide a resin composition. The resulting resin composition was examined by the procedure described above to measure the copper foil adhesion strength, soldering heat resistance, Tg, relative dielectric constant, and dissipation factor.

### Example 16

To 10.67 g (solid content 3.2 g) of the polyimide solution B prepared in Example 2, 2.15 g (solid content 1.4 g) of OPE-2st-1200 (solid content 65 wt %, toluene solution), 0.2 g of BMI4000, 1.2 g of TEPIC-FL, and 0.06 g of 2P4MZ were added and mixed by stirring to provide a resin composition. The resulting resin composition was examined by the procedure described above to measure the copper foil adhesion strength, soldering heat resistance, Tg, relative dielectric constant, and dissipation factor.

### Example 17

To 10.00 g (solid content 3.0 g) of the polyimide solution B prepared in Example 2, 2.15 g (solid content 1.4 g) of OPE-2st-1200 (solid content 65 wt %, toluene solution), 0.4 g of BMI4000, 1.2 g of TEPIC-FL, and 0.06 g of 2P4MZ were added and mixed by stirring to provide a resin composition. The resulting resin composition was examined by the procedure described above to measure the copper foil adhesion strength, soldering heat resistance, Tg, relative dielectric constant, and dissipation factor.

### Example 18

To 10.00 g (solid content 3.0 g) of the polyimide solution B prepared in Example 2, 2.15 g (solid content 1.4 g) of OPE-2st-1200 (solid content 65 wt %, toluene solution), 0.4 g of BMI4000, 1.2 g of TEPIC-FL, 0.06 g of 2P4MZ, and 0.06 g of DCP were added and mixed by stirring to provide a resin composition. The resulting resin composition was examined by the procedure described above to measure the copper foil adhesion strength, soldering heat resistance, Tg, relative dielectric constant, and dissipation factor.

### Example 19

To 10.00 g (solid content 3.0 g) of the polyimide solution B prepared in Example 2, 2.15 g (solid content 1.4 g) of OPE-2st-1200 (solid content 65 wt %, toluene solution), 0.59 g (solid content 0.4 g) of MIR-3000-70MT (solid content 68.2 wt %, toluene solution), 1.2 g of TEPIC-FL, 0.06 g of 2P4MZ, and 0.06 g of DCP were added and mixed by stirring to provide a resin composition. The resulting resin composition was examined by the procedure described above to measure the copper foil adhesion strength, soldering heat resistance, Tg, relative dielectric constant, and dissipation factor.

### Example 20

To 10.00 g (solid content 3.0 g) of the polyimide solution B prepared in Example 2, 2.15 g (solid content 1.4 g) of OPE-2st-1200 (solid content 65 wt %, toluene solution), 0.59 g (solid content 0.4 g) of MIR-3000-70MT (solid content 68.2 wt %, toluene solution), 1.2 g of TEPIC-FL, 0.06 g of SI-B4, and 0.06 g of DCP were added and mixed by stirring to provide a resin composition. The resulting resin composition was examined by the procedure described above to measure the copper foil adhesion strength, soldering heat resistance, Tg, relative dielectric constant, and dissipation factor.

### Example 21

To 10.00 g (solid content 3.0 g) of the polyimide solution B prepared in Example 2, 2.15 g (solid content 1.4 g) of OPE-2st-1200 (solid content 65 wt %, toluene solution), 1.17 g (solid content 0.8 g) of MIR-3000-70MT (solid content 68.2 wt %, toluene solution), 0.8 g of TEPIC-FL, 0.06 g of 2P4MZ, and 0.06 g of DCP were added and mixed by stirring to provide a resin composition. The resulting resin composition was examined by the procedure described above to measure the copper foil adhesion strength, soldering heat resistance, Tg, relative dielectric constant, and dissipation factor.

### Example 22

To 10.00 g (solid content 3.0 g) of the polyimide solution B prepared in Example 2, 2.15 g (solid content 1.4 g) of OPE-2st-1200 (solid content 65 wt %, toluene solution), 1.47 g (solid content 1.0 g) of MIR-3000-70MT (solid content 68.2 wt %, toluene solution), 0.6 g of TEPIC-FL, 0.06 g of 2P4MZ, and 0.06 g of DCP were added and mixed by stirring to provide a resin composition. The resulting resin composition was examined by the procedure described above to measure the copper foil adhesion strength, soldering heat resistance, Tg, relative dielectric constant, and dissipation factor.

### Example 23

To 10.00 g (solid content 3.0 g) of the polyimide solution B prepared in Example 2, 2.15 g (solid content 1.4 g) of OPE-2st-1200 (solid content 65 wt %, toluene solution), 1.47 g (solid content 1.0 g) of MIR-3000-70MT (solid content 68.2 wt %, toluene solution), 0.6 g of TEPIC-FL, 0.06 g of SI-B4, and 0.06 g of DCP were added and mixed by stirring to provide a resin composition. The resulting resin composition was examined by the procedure described above to measure the copper foil adhesion strength, soldering heat resistance, Tg, relative dielectric constant, and dissipation factor.

### Example 24

To 10.00 g (solid content 3.0 g) of the polyimide solution B prepared in Example 2, 2.21 g (solid content 1.4 g) of OPE-2st-2200 (solid content 63.4 wt %, toluene solution), 1.47 g (solid content 1.0 g) of MIR-3000-70MT (solid content 68.2 wt %, toluene solution), 0.6 g of TEPIC-FL, 0.06 g of 2P4MZ, and 0.06 g of DCP were added and mixed by stirring to provide a resin composition. The resulting resin composition was examined by the procedure described above to measure the copper foil adhesion strength, soldering heat resistance, Tg, relative dielectric constant, and dissipation factor.

### Example 25

To 10.00 g (solid content 3.0 g) of the polyimide solution B prepared in Example 2, 1.4 g of SA-90, 1.47 g (solid content 1.0 g) of MIR-3000-70MT (solid content 68.2 wt %, toluene solution), 0.6 g of TEPIC-FL, 0.06 g of 2P4MZ, and 0.06 g of DCP were added and mixed by stirring to provide a resin composition. The resulting resin composition was examined by the procedure described above to measure the copper foil adhesion strength, soldering heat resistance, Tg, relative dielectric constant, and dissipation factor.

### Example 26

To 10.00 g (solid content 3.0 g) of the polyimide solution B prepared in Example 2, 2.15 g (solid content 1.4 g) of OPE-2st-1200 (solid content 65 wt %, toluene solution), 1.47 g (solid content 1.0 g) of MIR-3000-70MT (solid content 68.2 wt %, toluene solution), 0.6 g of JER825, 0.06 g of 2P4MZ, and 0.06 g of DCP were added and mixed by stirring to provide a resin composition. The resulting resin composition was examined by the procedure described above to measure the copper foil adhesion strength, soldering heat resistance, Tg, relative dielectric constant, and dissipation factor.

### Example 27

To 10.00 g (solid content 3.0 g) of the polyimide solution B prepared in Example 2, 2.15 g (solid content 1.4 g) of OPE-2st-1200 (solid content 65 wt %, toluene solution), 1.47 g (solid content 1.0 g) of MIR-3000-70MT (solid content 68.2 wt %, toluene solution), 0.6 g of E101, 0.06 g of 2P4MZ, and 0.06 g of DCP were added and mixed by stirring to provide a resin composition. The resulting resin composition was examined by the procedure described above to measure the copper foil adhesion strength, soldering heat resistance, Tg, relative dielectric constant, and dissipation factor.

### Example 28

To 10.00 g (solid content 3.0 g) of the polyimide solution B prepared in Example 2, 2.15 g (solid content 1.4 g) of OPE-2st-1200 (solid content 65 wt %, toluene solution), 1.47 g (solid content 1.0 g) of MIR-3000-70MT (solid content 68.2 wt %, toluene solution), 0.3 g of JER825, 0.3 g of E101, 0.06 g of 2P4MZ, and 0.06 g of DCP were added and mixed by stirring to provide a resin composition. The resulting resin composition was examined by the procedure described above to measure the copper foil adhesion strength, soldering heat resistance, Tg, relative dielectric constant, and dissipation factor.

### Example 29

To 10.00 g (solid content 3.0 g) of the polyimide solution B prepared in Example 2, 2.15 g (solid content 1.4 g) of OPE-2st-1200 (solid content 65 wt %, toluene solution), 0.4 g of BMI4000, 1.2 g of JER825, 0.06 g of 2P4MZ, and 0.06 g of DCP were added and mixed by stirring to provide a resin composition. The resulting resin composition was examined by the procedure described above to measure the copper foil adhesion strength, soldering heat resistance, Tg, relative dielectric constant, and dissipation factor.

### Example 30

To 10.00 g (solid content 3.0 g) of the polyimide solution B prepared in Example 2, 2.15 g (solid content 1.4 g) of OPE-2st-1200 (solid content 65 wt %, toluene solution), 0.4 g of BMI4000, 1.2 g of E101, 0.06 g of 2P4MZ, and 0.06 g of DCP were added and mixed by stirring to provide a resin composition. The resulting resin composition was examined by the procedure described above to measure the copper foil adhesion strength, soldering heat resistance, Tg, relative dielectric constant, and dissipation factor.

### Example 31

To 10.00 g (solid content 3.0 g) of the polyimide solution B prepared in Example 2, 2.15 g (solid content 1.4 g) of OPE-2st-1200 (solid content 65 wt %, toluene solution), 0.4 g of BMI4000, 0.6 g of JER825, 0.6 g of E101, 0.06 g of 2P4MZ, and 0.06 g of DCP were added and mixed by stirring to provide a resin composition. The resulting resin composition was examined by the procedure described above to measure the copper foil adhesion strength, soldering heat resistance, Tg, relative dielectric constant, and dissipation factor.

### Example 32

To 10.00 g (solid content 3.0 g) of the polyimide solution B prepared in Example 2, 2.62 g (solid content 1.7 g) of OPE-2st-1200 (solid content 65 wt %, toluene solution), 1.91 g (solid content 1.3 g) of MIR-3000-70MT (solid content 68.2 wt %, toluene solution), and 0.06 g of DCP were added and mixed by stirring to provide a resin composition. The resulting resin composition was examined by the procedure described above to measure the copper foil adhesion strength, soldering heat resistance, Tg, relative dielectric constant, and dissipation factor.

### Example 33

To 3.33 g (solid content 1.0 g) of the polyimide solution B prepared in Example 2, 5.38 g (solid content 3.5 g) of OPE-2st-1200 (solid content 65 wt %, toluene solution), 1.47 g (solid content 1.0 g) of MIR-3000-70MT (solid content 68.2 wt %, toluene solution), 0.5 g of TEPIC-FL, 0.06 g of 2P4MZ, and 0.06 g of DCP were added and mixed by stirring to provide a resin composition. The resulting resin composition was examined by the procedure described above to measure the copper foil adhesion strength, soldering heat resistance, Tg, relative dielectric constant, and dissipation factor.

### Example 34

To 10.00 g (solid content 3.0 g) of the polyimide solution B prepared in Example 2, 0.31 g (solid content 0.2 g) of OPE-2st-1200 (solid content 65 wt %, toluene solution), 0.15 g (solid content 0.1 g) of MIR-3000-70MT (solid content 68.2 wt %, toluene solution), 2.7 g of TEPIC-FL, 0.3 g of E101, 0.06 g of 2P4MZ, and 0.06 g of DCP were added and mixed by stirring to provide a resin composition. The resulting resin composition was examined by the procedure described above to measure the copper foil adhesion strength, soldering heat resistance, Tg, relative dielectric constant, and dissipation factor.

### Example 35

To 10.00 g (solid content 3.0 g) of the polyimide solution B prepared in Example 2, 2.15 g (solid content 1.4 g) of OPE-2st-1200 (solid content 65 wt %, toluene solution), 1.47 g (solid content 1.0 g) of MIR-3000-70MT (solid content 68.2 wt %, toluene solution), 0.6 g of TEPIC-FL, 0.06 g of 2P4MZ, 0.06 g of DCP, and 0.3 g of KBM1003 were added and mixed by stirring to provide a resin composition. The resulting resin composition was examined by the procedure described above to measure the copper foil adhesion strength, soldering heat resistance, Tg, relative dielectric constant, and dissipation factor.

### Example 36

To 10.00 g (solid content 3.0 g) of the polyimide solution B prepared in Example 2, 2.15 g (solid content 1.4 g) of OPE-2st-1200 (solid content 65 wt %, toluene solution), 1.47 g (solid content 1.0 g) of MIR-3000-70MT (solid content 68.2 wt %, toluene solution), 0.6 g of TEPIC-FL, 0.06 g of 2P4MZ, 0.06 g of DCP, and 0.3 g of KBM1403 were added and mixed by stirring to provide a resin composition. The resulting resin composition was examined by the procedure described above to measure the copper foil adhesion strength, soldering heat resistance, Tg, relative dielectric constant, and dissipation factor.

### Comparative Example 1

In a 500 ml four neck flask equipped with a stirrer, thermometer, nitrogen supply tube, and dropping funnel, 145.00 g of γBL and 31.02 g of ODPA were fed and dissolved by stirring at 60° C. in a nitrogen atmosphere. Then, while stirring at 60° C., 32.02 g of TFMB was added and stirred for 1 hour. Subsequently, the temperature was raised by heating to 180° C. and stirring was performed for 3 hours, followed by cooling to room temperature to prepare a polyimide solution I (solid content 30.0 wt %). The weight average molecular weight of the polyimide was measured to be 47,310, and its Tg and imidization rate were measured to be 226° C. and 100%, respectively.

A 10.0 g portion (solid content 3.0 g) of the polyimide solution I prepared in this way was mixed with the components listed in Table 4 by the same procedure as in Example 19 to provide a resin composition. The resulting resin composition was examined by the procedure described above to measure the copper foil adhesion strength, soldering heat resistance, Tg, relative dielectric constant, and dissipation factor.

### Comparative Example 2

To 10.00 g (solid content 3.0 g) of the polyimide solution B prepared in Example 2, 4.62 g (solid content 3.0 g) of OPE-2st-1200 (solid content 65 wt %, toluene solution) and 0.06 g of DCP were added and mixed by stirring to provide a resin composition. The resulting resin composition was examined by the procedure described above to measure the copper foil adhesion strength, soldering heat resistance, Tg, relative dielectric constant, and dissipation factor.

TABLE 1

| | | Poly- | Poly- | Poly- | Poly- | Poly- | Poly- | Poly- | Poly- | Poly- |
|---|---|---|---|---|---|---|---|---|---|---|
| | | Imide | Imide | Imide | Imide | Imide | Imide | Imide | Imide | Imide |
| Item | | A | B | C | D | E | F | G | H | I |
| Anhydride | BSAA | 100 | | | | | | | | |
| monomer | TBIS- | | 100 | | | | | | | |
| (mol %) | DMPN | | | | 100 | 100 | 100 | 100 | | |
| | ODPA | | | 100 | | | | | 100 | 100 |
| Diamine | TFMB | 50 | 50 | 50 | 50 | 50 | | | 80 | 100 |
| monomer | mTB | | | | | | | 50 | | |
| (mol %) | BAHF | | | | | | 50 | | | |
| | LP7100 | 50 | 50 | 50 | | | 50 | 50 | 20 | |
| | X-22-9409 | | | | 50 | | | | | |
| | X-22-1660B-3 | | | | | 50 | | | | |
| | Versamine | | | | | | | | | |
| | 551 | | | | | | | | | |
| | Priamine | | | | | | | | | |
| | 1075 | | | | | | | | | |
| Properties | imide | 384.23 | 488.57 | 279.28 | 761.44 | 1511.44 | 500.07 | 461.58 | 290.04 | 297.21 |
| | group | | | | | | | | | |
| | equivalent | | | | | | | | | |
| | Tg (° C.) | 125 | 168 | 178 | 65 | -5 | 164 | 169 | 208 | 226 |
| | imidization | 100 | 100 | 100 | 100 | 100 | 100 | 100 | 100 | 100 |
| | rate (%) | | | | | | | | | |
| | weight | 36,400 | 43,210 | 41,630 | 33,400 | 29,540 | 28,580 | 44,590 | 43,200 | 47,310 |
| | average | | | | | | | | | |
| | molecular | | | | | | | | | |
| | weight | | | | | | | | | |
| | | | | Poly- | Poly- | Poly- | Poly- | Poly- | Poly- | Poly- |
| | | | | Imide | Imide | Imide | Imide | Imide | Imide | Imide |
| | | Item | | J | K | L | M | N | O | P |
| | | Anhydride | BSAA | 100 | 100 | 100 | 100 | 100 | 100 | 100 |
| | | monomer | TBIS- | | | | | | | |
| | | (mol %) | DMPN | | | | | | | |
| | | | ODPA | | | | | | | |
| | | Diamine | TFMB | 70 | 70 | 85 | 60 | 50 | 65 | 55 |
| | | monomer | mTB | | | | | | | |
| | | (mol %) | BAHF | | | | | | | |
| | | | LP7100 | | | | 10 | 20 | 20 | 30 |
| | | | X-22-9409 | | | | | | | |
| | | | X-22-1660B-3 | | | | | | | |
| | | | Versamine | 30 | | | | | | |
| | | | 551 | | | | | | | |
| | | | Priamine | | 30 | 15 | 30 | 30 | 15 | 15 |
| | | | 1075 | | | | | | | |
| | | Properties | imide | 433.97 | 434.57 | 418.44 | 418.56 | 402.55 | 386.44 | 370.43 |
| | | | group | | | | | | | |
| | | | equivalent | | | | | | | |
| | | | Tg (° C.) | 139 | 134 | 162 | 124 | 114 | 149 | 131 |
| | | | imidization | 100 | 100 | 100 | 100 | 100 | 100 | 100 |
| | | | rate (%) | | | | | | | |
| | | | weight | 32,100 | 31,200 | 36,800 | 30,100 | 28,200 | 29,800 | 29,100 |
| | | | average | | | | | | | |
| | | | molecular | | | | | | | |
| | | | weight | | | | | | | |

TABLE 2

| | | Exam- | Exam- | Exam- | Exam- | Exam- | Exam- | Exam- | Exam- |
|---|---|---|---|---|---|---|---|---|---|
| Item | | ple 1 | ple 2 | ple 3 | ple 4 | ple 5 | ple 6 | ple 7 | ple 8 |
| Polyimide resin (A) | polyimide A | 3.6 | | | | | | | |
| (g) | polyimide B | | 3.6 | | | | | | |
| | polyimide C | | | 3.6 | | | | | |
| | polyimide D | | | | 3.6 | | | | |
| | polyimide E | | | | | 3.6 | | | |
| | polyimide F | | | | | | 3.6 | | |
| | polyimide G | | | | | | | 3.6 | |
| | polyimide H | | | | | | | | 3.6 |
| | polyimide I | | | | | | | | |
| | polyimide J | | | | | | | | |
| | polyimide K | | | | | | | | |
| | polyimide L | | | | | | | | |
| | polyimide M | | | | | | | | |
| | polyimide N | | | | | | | | |
| | polyimide O | | | | | | | | |
| | polyimide P | | | | | | | | |
| Phenylene ether | OPE-2st-1200 | 1 | 1 | 1 | 1 | 1 | 1 | 1 | 1 |
| resin (B) (g) | OPE-2st-2200 | | | | | | | | |
| | SA-90 | | | | | | | | |
| | content (wt %) | 16.5 | 16.5 | 16.5 | 16.5 | 16.5 | 16.5 | 16.5 | 16.5 |
| Maleimide resin | BMI4000 | 0.2 | 0.2 | 0.2 | 0.2 | 0.2 | 0.2 | 0.2 | 0.2 |
| (C) (g) | MIR-3000-70MT | | | | | | | | |
| Epoxy resin (D) (g) | JER825 | | | | | | | | |
| | E101 | | | | | | | | |
| | TEPIC-FL | 1.2 | 1.2 | 1.2 | 1.2 | 1.2 | 1.2 | 1.2 | 1.2 |
| Curing assistant | 2P4MZ | 0.06 | 0.06 | 0.06 | 0.06 | 0.06 | 0.06 | 0.06 | 0.06 |
| (E) (g) | SI-B4 | | | | | | | | |
| Organic peroxide | DCP | | | | | | | | |
| (g) | | | | | | | | | |
| Adhesion improver | KBM1003 | | | | | | | | |
| (g) | KBM1403 | | | | | | | | |
| | | | Exam- | Exam- | Exam- | Exam- | Exam- | Exam- | Exam- |
| | Item | | ple 9 | ple 10 | ple 11 | ple 12 | ple 13 | ple 14 | ple 15 |
| | Polyimide resin (A) | polyimide A | | | | | | | |
| | (g) | polyimide B | | | | | | | |
| | | polyimide C | | | | | | | |
| | | polyimide D | | | | | | | |
| | | polyimide E | | | | | | | |
| | | polyimide F | | | | | | | |
| | | polyimide G | | | | | | | |
| | | polyimide H | | | | | | | |
| | | polyimide I | | | | | | | |
| | | polyimide J | 3.6 | | | | | | |
| | | polyimide K | | 3.6 | | | | | |
| | | polyimide L | | | 3.6 | | | | |
| | | polyimide M | | | | 3.6 | | | |
| | | polyimide N | | | | | 3.6 | | |
| | | polyimide O | | | | | | 3.6 | |
| | | polyimide P | | | | | | | 3.6 |
| | Phenylene ether | OPE-2st-1200 | 1 | 1 | 1 | 1 | 1 | 1 | 1 |
| | resin (B) (g) | OPE-2st-2200 | | | | | | | |
| | | SA-90 | | | | | | | |
| | | content (wt %) | 16.5 | 16.5 | 16.5 | 16.5 | 16.5 | 16.5 | 16.5 |
| | Maleimide resin | BMI4000 | 0.2 | 0.2 | 0.2 | 0.2 | 0.2 | 0.2 | 0.2 |
| | (C) (g) | MIR-3000-70MT | | | | | | | |
| | Epoxy resin (D) (g) | JER825 | | | | | | | |
| | | E101 | | | | | | | |
| | | TEPIC-FL | 1.2 | 1.2 | 1.2 | 1.2 | 1.2 | 1.2 | 1.2 |
| | Curing assistant | 2P4MZ | 0.06 | 0.06 | 0.06 | 0.06 | 0.06 | 0.06 | 0.06 |
| | (E) (g) | SI-B4 | | | | | | | |
| | Organic peroxide | DCP | | | | | | | |
| | (g) | | | | | | | | |
| | Adhesion improver | KBM1003 | | | | | | | |
| | (g) | KBM1403 | | | | | | | |

TABLE 3

| | | Example | Example | Example | Example | Example | Example | Example | Example | Example | Example | Example |
|---|---|---|---|---|---|---|---|---|---|---|---|---|
| Item | | 16 | 17 | 18 | 19 | 20 | 21 | 22 | 23 | 24 | 25 | 26 |
| Polyimide | polyimide A | | | | | | | | | | | |
| resin (A) | polyimide B | 3.2 | 3 | 3 | 3 | 3 | 3 | 3 | 3 | 3 | 3 | 3 |
| (g) | polyimide C | | | | | | | | | | | |
| | polyimide D | | | | | | | | | | | |
| | polyimide E | | | | | | | | | | | |
| | polyimide F | | | | | | | | | | | |
| | polyimide G | | | | | | | | | | | |
| | polyimide H | | | | | | | | | | | |
| | polyimide I | | | | | | | | | | | |
| | polyimide J | | | | | | | | | | | |
| | polyimide K | | | | | | | | | | | |
| | polyimide L | | | | | | | | | | | |
| | polyimide M | | | | | | | | | | | |
| | polyimide N | | | | | | | | | | | |
| | polyimide 0 | | | | | | | | | | | |
| | polyimide P | | | | | | | | | | | |
| Phenylene ether | OPE-2st-1200 | 1.4 | 1.4 | 1.4 | 1.4 | 1.4 | 1.4 | 1.4 | 1.4 | | | 1.4 |
| resin (B) (g) | OPE-2st-2200 | | | | | | | | | 1.4 | | |
| | SA-90 | | | | | | | | | | 1.4 | |
| | content (wt %) | 23.1 | 23.1 | 22.9 | 22.9 | 22.9 | 22.9 | 22.9 | 22.9 | 22.9 | 22.9 | 22.9 |
| Maleimide | BMI4000 | 0.2 | 0.4 | 0.4 | | | | | | | | |
| resin (C) | MIR-3000-70MT | | | | 0.4 | 0.4 | 0.8 | 1 | 1 | 1 | 1 | 1 |
| (g) | | | | | | | | | | | | |
| Epoxy resin | JER825 | | | | | | | | | | | 0.6 |
| (D) (g) | E101 | | | | | | | | | | | |
| | TEPIC-FL | 1.2 | 1.2 | 1.2 | 1.2 | 1.2 | 0.8 | 0.6 | 0.6 | 0.6 | 0.6 | |
| Curing | 2P4MZ | 0.06 | 0.06 | 0.06 | 0.06 | | 0.06 | 0.06 | | 0.06 | 0.06 | 0.06 |
| assistant (E) | SI-B4 | | | | | 0.06 | | | 0.06 | | | |
| (g) | | | | | | | | | | | | |
| Organic | DCP | 0.06 | 0.06 | 0.06 | 0.06 | 0.06 | 0.06 | 0.06 | 0.06 | 0.06 | | |
| peroxide | | | | | | | | | | | | |
| (g) | | | | | | | | | | | | |
| Adhesion | KBM1003 | | | | | | | | | | | |
| improver | | | | | | | | | | | | |
| (g) | KBM1403 | | | | | | | | | | | |

TABLE 4

| | | | | | | | | | | | | Compar- | Compar- |
|---|---|---|---|---|---|---|---|---|---|---|---|---|---|
| | | Exam- | Exam- | Exam- | Exam- | Exam- | Exam- | Exam- | Exam- | Exam- | Exam- | ative | ative |
| | | ple | ple | ple | ple | ple | ple | ple | ple | ple | ple | exam- | exam- |
| Item | | 27 | 28 | 29 | 30 | 31 | 32 | 33 | 34 | 35 | 36 | ple 1 | ple 2 |
| Polyimide | polyimide A | | | | | | | | | | | | |
| resin | polyimide B | 3 | 3 | 3 | 3 | 3 | 1 | 3 | 3 | 3 | 3 | | 3 |
| (A) (g) | polyimide C | | | | | | | | | | | | |
| | polyimide D | | | | | | | | | | | | |
| | polyimide E | | | | | | | | | | | | |
| | polyimide F | | | | | | | | | | | | |
| | polyimide G | | | | | | | | | | | | |
| | polyimide H | | | | | | | | | | | | |
| | polyimide I | | | | | | | | | | | 3 | |
| | polyimide J | | | | | | | | | | | | |
| | polyimide K | | | | | | | | | | | | |
| | polyimide L | | | | | | | | | | | | |
| | polyimide M | | | | | | | | | | | | |
| | polyimide N | | | | | | | | | | | | |
| | polyimide 0 | | | | | | | | | | | | |
| | polyimide P | | | | | | | | | | | | |
| Phenylene | OPE-2st-1200 | 1.4 | 1.4 | 1.4 | 1.4 | 1.7 | 3.5 | 0.2 | 1.4 | 1.4 | 1.4 | 1.4 | 3 |
| ether | OPE-2st-2200 | | | | | | | | | | | | |
| resin (B) | SA-90 | | | | | | | | | | | | |
| (g) | content (wt %) | 22.9 | 22.9 | 22.9 | 22.9 | 22.9 | 28.1 | 57.8 | 3.3 | 22.9 | 22.9 | 22.9 | 49.5 |
| Maleimide | BMI4000 | | | 0.4 | 0.4 | 0.4 | | | | | | | |
| resin | MIR-3000-70MT | 1 | 1 | | | | 1.3 | 1 | 0.1 | 1 | 1 | 1 | |
| (C) (g) | | | | | | | | | | | | | |
| Epoxy | JER825 | | 0.3 | 1.2 | | 0.6 | | | | | | | |
| resin (D) | E101 | 0.6 | 0.3 | | 1.2 | 0.6 | | | | | | | |
| (g) | TEPIC-FL | | | | | | | 0.5 | 2.7 | 0.6 | 0.6 | 0.6 | |
| Curing | 2P4MZ | 0.06 | 0.06 | 0.06 | 0.06 | 0.06 | | 0.06 | 0.06 | 0.06 | 0.06 | 0.06 | |
| assistant | SI-B4 | | | | | | | | | | | | |
| (E) (g) | | | | | | | | | | | | | |
| Organic | DCP | 0.06 | 0.06 | 0.06 | 0.06 | 0.06 | 0.06 | 0.06 | 0.06 | 0.06 | 0.06 | 0.06 | 0.06 |
| peroxide (g) | | | | | | | | | | | | | |
| Adhesion | KBM1003 | | | | | | | | | 0.3 | | | |
| improver (g) | KBM1403 | | | | | | | | | | 0.3 | | |

TABLE 5

| | Example | Example | Example | Example | Example | Example | Example | Example |
|---|---|---|---|---|---|---|---|---|
| Item | 1 | 2 | 3 | 4 | 5 | 6 | 7 | 8 |
| Copper foil | 10.0 | 8.0 | 8.0 | 12.0 | 10.0 | 8.0 | 8.0 | 6.0 |
| adhesion | | | | | | | | |
| strength | | | | | | | | |
| (N/cm) | | | | | | | | |
| Soldering | good | good | good | good | good | good | good | good |
| heat | | | | | | | | |
| resistance | | | | | | | | |
| Tg (° C.) | 118 | 136 | 125 | 78 | 28 | 134 | 135 | 153 |
| Relative | 2.7 | 2.8 | 3.2 | 2.5 | 2.5 | 3 | 2.9 | 3.2 |
| dielectric | | | | | | | | |
| constant | | | | | | | | |
| Dissipation | 0.006 | 0.008 | 0.011 | 0.007 | 0.007 | 0.013 | 0.01 | 0.012 |
| factor | | | | | | | | |
| | | Example | Example | Example | Example | Example | Example | Example |
| | Item | 9 | 10 | 11 | 12 | 13 | 14 | 15 |
| | Copper foil | 9.0 | 8.0 | 7.0 | 9.0 | 9.0 | 8.0 | 9.0 |
| | adhesion | | | | | | | |
| | strength | | | | | | | |
| | (N/cm) | | | | | | | |
| | Soldering | good | good | good | good | good | good | good |
| | heat | | | | | | | |
| | resistance | | | | | | | |
| | Tg (° C.) | 130 | 127 | 155 | 116 | 106 | 141 | 134 |
| | Relative | 2.9 | 2.8 | 3.0 | 2.7 | 2.6 | 2.9 | 2.7 |
| | dielectric | | | | | | | |
| | constant | | | | | | | |
| | Dissipation | 0.006 | 0.005 | 0.007 | 0.005 | 0.004 | 0.005 | 0.004 |
| | factor | | | | | | | |

TABLE 6

| | Example | Example | Example | Example | Example | Example | Example | Example | Example | Example | Example |
|---|---|---|---|---|---|---|---|---|---|---|---|
| Item | 16 | 17 | 18 | 19 | 20 | 21 | 22 | 23 | 24 | 25 | 26 |
| Copper foil | 10.0 | 11.0 | 10.0 | 12.0 | 14.0 | 12.0 | 10.0 | 12.0 | 10.0 | 10.0 | 16.0 |
| adhesion | | | | | | | | | | | |
| strength | | | | | | | | | | | |
| (N/cm) | | | | | | | | | | | |
| Soldering | good | good | good | good | good | good | good | good | good | good | good |
| heat | | | | | | | | | | | |
| resistance | | | | | | | | | | | |
| Tg (° C.) | 129 | 129 | 132 | 130 | 185 | 130 | 130 | 182 | 132 | 118 | 120 |
| Relative | 2.7 | 2.7 | 2.6 | 2.7 | 2.8 | 2.8 | 2.8 | 2.8 | 2.7 | 2.9 | 3 |
| dielectric | | | | | | | | | | | |
| constant | | | | | | | | | | | |
| Dissipation | 0.008 | 0.008 | 0.006 | 0.007 | 0.007 | 0.006 | 0.003 | 0.005 | 0.004 | 0.008 | 0.007 |
| factor | | | | | | | | | | | |

TABLE 7

| | Example | Example | Example | Example | Example | Example | Example |
|---|---|---|---|---|---|---|---|
| Item | 27 | 28 | 29 | 30 | 31 | 32 | 33 |
| Copper foil | 14.0 | 16.0 | 18.0 | 15.0 | 16.0 | 6.0 | 5.0 |
| adhesion strength | | | | | | | |
| (N/cm) | | | | | | | |
| Soldering heat | good | good | good | good | good | good | good |
| resistance | | | | | | | |
| Tg(° C.) | 109 | 113 | 115 | 101 | 107 | 132 | 112 |
| Relative dielectric | 2.6 | 2.7 | 3.2 | 2.4 | 2.5 | 2.8 | 2.6 |
| constant | | | | | | | |
| Dissipation factor | 0.006 | 0.004 | 0.01 | 0.006 | 0.004 | 0.003 | 0.005 |
| | | | Example | Example | Example | Comparative | Comparative |
| | | Item | 34 | 35 | 36 | example 1 | example 2 |
| | | Copper foil | 18.0 | 13.0 | 13.0 | 2.0 | 1.0 |
| | | adhesion strength | | | | | |
| | | (N/cm) | | | | | |
| | | Soldering heat | good | good | good | inferior | inferior |
| | | resistance | | | | | |
| | | Tg(° C.) | 142 | 135 | 138 | 146 | 136 |
| | | Relative dielectric | 3.3 | 2.8 | 2.8 | 3.4 | 2.7 |
| | | constant | | | | | |
| | | Dissipation factor | 0.015 | 0.005 | 0.003 | 0.025 | 0.003 |

### EXPLANATION OF NUMERALS

11 antenna part
12 matching circuit
13 MSL feeder line
14 feeding point
15 ground
16 insulation film
J thickness of ground wiring
K thickness of antenna wiring
M length of matching circuit
L length of antenna part
W width of antenna part
201 IC chip
202 electrode pad
203 second via wiring
204 planar antenna wiring
205 second molding resin
206 ground
207 first via wiring
208 first molding resin
209 copper wiring
210 insulation film
211 barrier metal
212 solder bump

1. A thermosetting resin composition comprising the components of (A1), (B), and (C) specified below:
polyimide resin (A1): a polyimide resin containing a diamine residue as represented by the formula (8) and/or the formula (9), 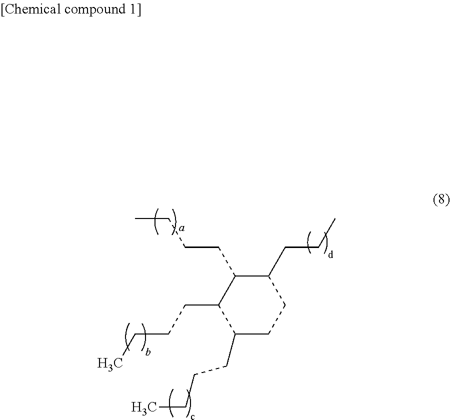
wherein in the formula (8), a, b, c, and d are each an integer number of 1 or higher and satisfy the relations of a+b=6 to 17, and c+d=8 to 19, and each broken line represents either a carbon-carbon single bond or a carbon-carbon double bond, 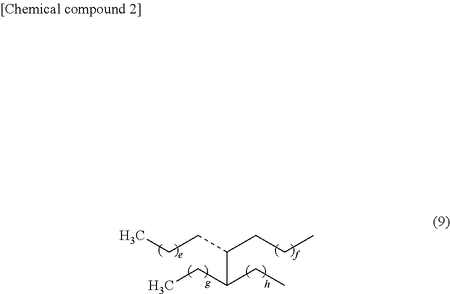
wherein in the formula (9), e, f, g, and h are each an integer number of 1 or higher and satisfy the relations of e+f=5 to 16, and g+h=8 to 19, and each broken line represents either a carbon-carbon single bond or a carbon-carbon double bond,
phenylene ether resin (B): a phenylene ether resin having a number average molecular weight of 500 or more and 5,000 or less and having at least one crosslinkable functional group selected from the group consisting of phenolic hydroxyl group, acryl group, vinyl group, and epoxy group located at a molecular chain end, and
maleimide resin (C): a maleimide resin.

2. A thermosetting resin composition comprising the components of (A2), (B), and (C) specified below:
polyimide resin (A2): a polyimide resin containing a diamine residue as represented by the formula (1), 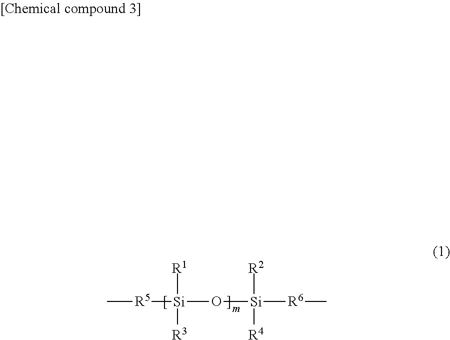
wherein in the formula (1), m represents an integer number of 1 to 60; R⁵ and R⁶ may be identical to or different from each other and they each represent an alkylene group containing 1 to 30 carbon atoms or a phenylene group; and R¹ to R⁴ may be identical to or different from each other and they each represent an alkyl group containing 1 to 30 carbon atoms, a phenyl group, or a phenoxy group,
phenylene ether resin (B): a phenylene ether resin having a number average molecular weight of 500 or more and 5,000 or less and having at least one crosslinkable functional group selected from the group consisting of phenolic hydroxyl group, acryl group, vinyl group, and epoxy group located at a molecular chain end, and
maleimide resin (C): a maleimide resin.

3. A thermosetting resin composition as set forth in claim 1, wherein the polyimide resin is the polyimide resin (A1) and the polyimide resin (A2).

4. A thermosetting resin composition as set forth in claim 3, wherein in the polyimide resin (A2), diamine residues represented by the formula (1) account for 20 to 80 mol % of all diamine residues, which account for 100 mol %, in the polyimide while at the same time, in the polyimide (A1), diamine residues represented by the formula (8) or formula (9) altogether account for 1 to 30 mol % of all diamine residues, which account for 100 mol %, in the polyimide, 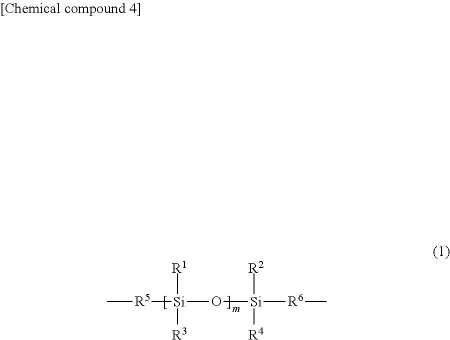
wherein in the formula (1), m represents an integer number of 1 to 60; R⁵ and R⁶ may be identical to or different from each other and they each represent an alkylene group containing 1 to 30 carbon atoms or a phenylene group; and R¹ to R⁴ may be identical to or different from each other and they each represent an alkyl group containing 1 to 30 carbon atoms, a phenyl group, or a phenoxy group, 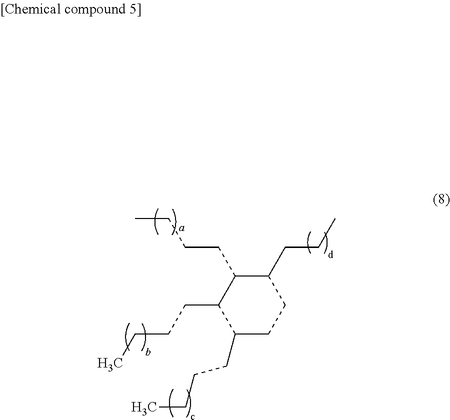
wherein in the formula (8), a, b, c, and d are each an integer number of 1 or higher and satisfy the relations of a+b=6 to 17, and c+d=8 to 19, and each broken line represents either a carbon-carbon single bond or a carbon-carbon double bond, 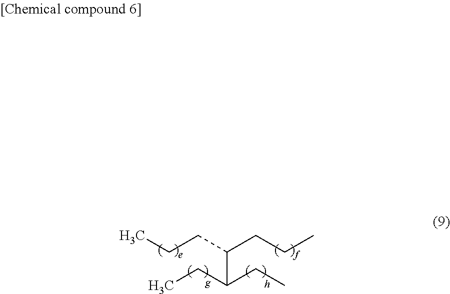
wherein in the formula (9), e, f, g, and h are each an integer number of 1 or higher and satisfy the relations of e+f=5 to 16, and g+h=8 to 19, and each broken line represents either a carbon-carbon single bond or a carbon-carbon double bond.

5. A thermosetting resin composition as set forth in claim 1, further comprising an epoxy resin (D) and a curing accelerator (E).

6. A thermosetting resin composition as set forth in claim 1, wherein the polyimide resin (A1) and the polyimide resin (A2) each have an imide group equivalent of 350 or more and 1,000 or less.

7. A thermosetting resin composition as set forth in claim 1, wherein the polyimide resin (A1) and the polyimide resin (A2) each contain a diamine residue that has a structure as represented by the formula (3), 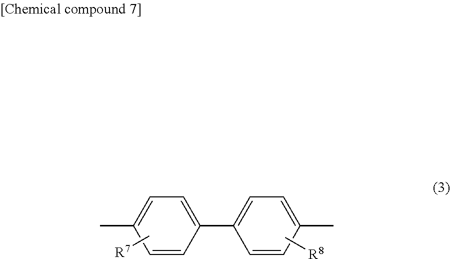
wherein in the formula (3), R⁷ and R⁸ may be identical to or different from each other and they each represent an alkyl group containing 1 to 30 carbon atoms, an alkoxy group, a fluoroalkyl group, a phenyl group, or a phenoxy group.

8. A thermosetting resin composition as set forth in claim 1, wherein the polyimide resin (A1) and the polyimide resin (A2) each have a glass transition temperature (Tg) of 100° C. or more and 200° C. or less.

9. A thermosetting resin composition as set forth in claim 1, wherein the phenylene ether resin (B) accounts for 5 wt % or more and 50 wt % or less relative to 100 wt % of the thermosetting resin composition.

10. A thermosetting resin composition as set forth in claim 1, further comprising a silane coupling agent (F) as represented by the formula (12), 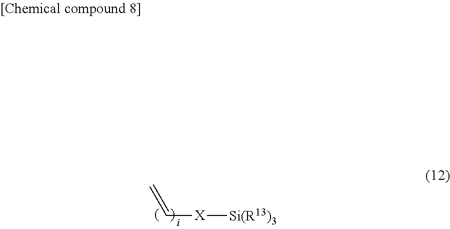
wherein in the formula (12), X is an aliphatic or aromatic divalent hydrocarbon group containing 1 to 30 carbon atoms or a single bond; the R¹³ groups may be identical to or different from each other and are each a halogen atom, an alkyl group containing 1 to 6 carbon atoms, an alkoxy group containing 1 to 6 carbon atoms, a phenyl group, a hydroxyl group, or a phenoxy group; i is an integer number of 1 to 3, and at least one of the plurality of R¹³ groups is a halogen atom or an alkoxy group containing 1 to 6 carbon atoms.

11. A thermosetting resin composition as set forth in claim 1, wherein the maleimide resin (C) contains polymaleimide resin molecules each having N maleimide groups (each N is an integer number and the average of N's is larger than 2 and smaller than 30).

12. A thermosetting resin sheet comprising a support and a thermosetting resin composition as set forth in claim 1 in the form of a layer in a non-heat-cured state laid thereon.

13. A cured film produced by curing a thermosetting resin composition as set forth in claim 1.

14. An electronic component comprising a cured film as set forth in claim 13.

15. An electronic component comprising an antenna element having at least one antenna wiring layer and a cured film as set forth in claim 13, wherein:
the antenna wiring layer contains at least one or more selected from the group consisting of meander type loop antenna, coil type loop antenna, meander type monopole antenna, meander type dipole antenna, and microstrip antenna; each antenna part in the antenna wiring layer has an exclusive area of 1,000 mm² or less; and the cured film is an insulation film for insulation between the ground and the antenna wiring layer.

16. An electronic component comprising a semiconductor package containing at least a semiconductor element, a redistribution layer, a molding resin layer, and an antenna wiring layer, wherein:
the insulating layer in the redistribution layer and/or the molding resin layer contain a cured film as set forth in claim 13, and the molding resin layer is located between the ground and the antenna wiring layer.

17. An electronic component comprising an antenna element containing a stack of an antenna wiring layer and a cured film as set forth in claim 13, wherein:
the antenna wiring layer has a height of 50 to 200 μm and the cured film has a thickness of 80 to 300 μm.

18. An electronic device comprising an electronic component as set forth in claim 14.
